(19) United States
(12) Patent Application Publication
(10) Pub. No.: US 2018/0286979 A1
(43) Pub. Date: Oct. 4, 2018

(54) METHOD FOR MANUFACTURING A SILICON CARBIDE SEMICONDUCTOR DEVICE

(71) Applicant: Sumitomo Electric Industries, Ltd., Osaka-shi (JP)

(72) Inventor: Hiromu Shiomi, Tsukuba-shi (JP)

(21) Appl. No.: 15/994,343

(22) Filed: May 31, 2018

Related U.S. Application Data
(62) Division of application No. 15/129,712, filed on Jan. 12, 2017.

(51) Int. Cl. H01L 29/78; H01L 29/423; H01L 29/66; H01L 29/04; H01L 21/04; H01L 29/16

(52) U.S. Cl. CPC H01L 29/7827; H01L 29/4236; H01L 29/66068; H01L 29/1608; H01L 29/045; H01L 21/0465

(57) ABSTRACT

A step of forming a silicon carbide substrate includes steps of: forming a first impurity region having a first conductivity type by epitaxial growth; forming an embedded region by performing ion implantation into the first impurity region, the embedded region having a second conductivity type different from the first conductivity type, the embedded region being disposed cyclically; and forming a second impurity region by epitaxial growth, the second impurity region being in contact with the first impurity region and the embedded region, the second impurity region having the second conductivity type, the second impurity region having an impurity concentration lower than an impurity concentration of the embedded region. A trench is formed to have a side portion and a bottom portion. The trench is disposed at the same cycle as the embedded region.

### CROSS-REFERENCE TO RELATED APPLICATIONS

This application is a Divisional of U.S. patent application Ser. No. 15/129,712, filed Jan. 12, 2017, which is a 371 of International Application Number PCT/IB2015/053548, filed May 14, 2015, which claims the benefit of Japanese Patent Application No. 2014-068302, filed Mar. 28, 2014.

### TECHNICAL FIELD

The present invention relates to a silicon carbide semiconductor device and a method for manufacturing the silicon carbide semiconductor device, particularly, the present invention relates to a silicon carbide semiconductor device having a main surface provided with a trench and a method for manufacturing the silicon carbide semiconductor device.

### BACKGROUND ART

In recent years, in order to achieve high breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on resistance, and the like. Further, the semiconductor device thus adopting silicon carbide as its material has characteristics less deteriorated even under a high temperature environment than those of a semiconductor device adopting silicon as its material, advantageously.

For example, Japanese Patent Laying-Open No. 2008-147232 (Patent Document 1) describes a trench type MOSFET (Metal Oxide Semiconductor Field Effect Transistor) composed of silicon carbide. According to the MOSFET, in order to prevent punch-through from being caused by a short channel effect, a channel layer is set to have a thickness equal to or more than a length determined by a predetermined formula and a base layer has a lower end located at the drain electrode side relative to the lower end of a gate trench.

Moreover, Y. Nakano et al., “690V, 1.00 mΩcm² 4H-SiC Double-Trench MOSFETs”, Materials Science Forum Vols. 717-720 (2012) page 1069-1072 (Non-Patent Document 1) describes a MOSFET in which a breakdown voltage holding trench is formed adjacent to a switching trench and the bottom portion of the breakdown voltage holding trench is provided at the drain electrode side relative to the bottom portion of the switching trench. A p type base layer is provided below the breakdown voltage holding trench.

Furthermore, according to a trench type MOSFET described in WO 2013/157259 (Patent Document 2), a p type region is provided in contact with the bottom portion of the gate trench.

### CITATION LIST

### Patent Document

PTD 1: Japanese Patent Laying-Open No. 2008-147232

PTD 2: WO 2013/157259

### Non Patent Document

NPD 1: Y. Nakano et al., “690V, 1.00 mΩ² cm² 4H—SiC Double-Trench MOSFETs”, Materials Science Forum Vols. 717-720 (2012) page 1069-1072

### SUMMARY OF INVENTION

### Technical Problem

A vertical type power transistor achieves high breakdown voltage by way of a pn junction between a base layer and a drift layer. The breakdown voltage is designed by adjusting concentration and thickness of the drift layer to suppress electric field in the semiconductor to a predetermined value. When switching is made at an interface between the semiconductor and an insulating film, the insulating film is also exposed to a high electric field. Particularly, since silicon carbide has a high dielectric breakdown electric field, it is possible to design such that the electric field in the semiconductor is increased to achieve a high breakdown voltage; however, a structure for relaxing the high electric field is needed for the switching portion. In a trench type transistor, a cell pitch can be reduced, thereby increasing a degree of integration of cells and decreasing on resistance. However, electric field intensity in an angled region of the trench portion is high, with the result that breakdown voltage is decreased as compared with a planar type transistor.

According to the MOSFET described in Japanese Patent Laying-Open No. 2008-147232, in order to prevent electric field from being concentrated on the trench portion, the bottom portion of the trench is provided at the source electrode side relative to the end portion of the p type base layer located at the drain electrode side, thus preventing the electric field from being applied to the bottom portion of the trench due to a depletion layer expanding below the p type base layer. Moreover, according to the MOSFET described in Y. Nakano et al., “690V, 1.00 mΩ²cm² 4H—SiC Double-Trench MOSFETs”, Materials Science Forum Vols. 717-720 (2012) page 1069-1072, in order to produce the above-described structure, the breakdown voltage holding trench is formed adjacent to the switching trench and the p type base layer is provided below the breakdown voltage holding trench to form a depletion layer at a deep location, thus protecting a trench structure of a current control portion.

However, in each of the above structures, during on time, an effect of expanding current, which flows out of the current control portion, in the drift layer is hindered, resulting in increased on resistance. For example, in the case of a device having a high breakdown voltage of not less than 1200 V, particularly, in the case of a device having a high breakdown voltage of not less than 3300 V, an impurity concentration of the drift layer is decreased. Accordingly, the depletion layer of the p type base layer is expanded and the current flowing out of the channel is not effectively expanded in the drift layer, thus resulting in increased on resistance. Meanwhile, if a distance between the trench and the p type base layer is increased, the electric field in the trench cannot be sufficiently relaxed, thus resulting in deteriorated breakdown voltage of the MOSFET. On the other hand, if the distance between the gate trench and the p type base layer is decreased, the on resistance of the MOSFET is increased. In other words, the on resistance and the breakdown voltage are in a trade-off relation.

Furthermore, according to the MOSFET described in WO 2013/157259, the electric field in the bottom portion of the trench is relaxed by forming the p type region at the bottom portion of the trench. However, the electric field is concentrated on the side portion of the trench. This makes it difficult to maintain a sufficiently high breakdown voltage.

An object of one embodiment of the present invention is to provide a silicon carbide semiconductor device having reduced on resistance and improved breakdown voltage, as well as a method for manufacturing such a silicon carbide semiconductor device.

### SOLUTION TO PROBLEM

A method for manufacturing a silicon carbide semiconductor device according to one embodiment of the present invention includes the following steps. A silicon carbide substrate is formed to have a first main surface and a second main surface opposite to the first main surface. The step of forming the silicon carbide substrate includes steps of: forming a first impurity region having a first conductivity type by epitaxial growth; forming an embedded region by performing ion implantation into the first impurity region, the embedded region having a second conductivity type different from the first conductivity type, the embedded region being disposed cyclically; forming a second impurity region by epitaxial growth, the second impurity region being in contact with the first impurity region and the embedded region, the second impurity region having the second conductivity type, the second impurity region having an impurity concentration lower than an impurity concentration of the embedded region; and forming a third impurity region having the first conductivity type, the third impurity region being separated from the first impurity region by the second impurity region. A trench is formed to have a side portion and a bottom portion, the side portion extending to the first impurity region through the second impurity region and the third impurity region, the bottom portion being continuous to the side portion, the trench being disposed at the same cycle as the embedded region. A gate insulating film is formed in contact with the first impurity region, the second impurity region, and the third impurity region at the side portion of the trench.

A silicon carbide semiconductor device according to one embodiment of the present invention includes a silicon carbide substrate and a gate insulating film. The silicon carbide substrate has a first main surface and a second main surface opposite to the first main surface. The silicon carbide substrate includes a first impurity region, a second impurity region, a third impurity region, and an embedded region, the first impurity region having a first conductivity type, the second impurity region being in contact with the first impurity region, the second impurity region having a second conductivity type different from the first conductivity type, the third impurity region having the first conductivity type, the third impurity region being separated from the first impurity region by the second impurity region, the embedded region having the second conductivity type, the embedded region having an impurity concentration higher than an impurity concentration of the second impurity region, the embedded region extending from a portion of an end portion of the second impurity region at the second main surface side toward the second main surface. A trench is formed in the first main surface of the silicon carbide substrate to have a side portion and a bottom portion, the side portion being continuous to the first main surface, the bottom portion being continuous to the side portion. The gate insulating film is in contact with the first impurity region, the second impurity region, and the third impurity region at the side portion of the trench and in contact with the first impurity region at the bottom portion of the trench. The embedded region has locations each having an impurity concentration four times as large as an impurity concentration of the third impurity region, a distance being not more than 0.3 μm from a location closest to the third impurity region among the locations to a boundary portion between the third impurity region and the embedded region in a normal direction of the first main surface.

### ADVANTAGEOUS EFFECTS OF INVENTION

According to one embodiment of the present invention, there can be provided a silicon carbide semiconductor device having reduced on resistance and improved breakdown voltage, as well as a method for manufacturing such a silicon carbide semiconductor device.

### BRIEF DESCRIPTION OF DRAWINGS

FIG. 1 is a schematic cross sectional view for schematically illustrating a structure of a silicon carbide semiconductor device according to a first embodiment of the present invention.

FIG. 2 is a schematic cross sectional view for schematically illustrating a plane orientation of a silicon carbide substrate of the silicon carbide semiconductor device according to the first embodiment of the present invention.

FIG. 3 is a schematic plan view for schematically illustrating structures of trenches of the silicon carbide semiconductor device according to the first embodiment of the present invention.

FIG. 4 is a schematic plan view for schematically illustrating a positional relation between a trench and an embedded region in the silicon carbide semiconductor device according to the first embodiment of the present invention.

FIG. 5 schematically illustrates respective impurity concentrations in the second impurity region and the embedded region in the silicon carbide semiconductor device according to the first embodiment of the present invention.

FIG. 6 is a flowchart for schematically illustrating a method for manufacturing the silicon carbide semiconductor device according to the first embodiment of the present invention.

FIG. 7 is a schematic cross sectional view for schematically illustrating a first step of the method for manufacturing the silicon carbide semiconductor device according to the first embodiment of the present invention.

FIG. 8 is a schematic cross sectional view for schematically illustrating a second step of the method for manufacturing the silicon carbide semiconductor device according to the first embodiment of the present invention.

FIG. 9 is a schematic cross sectional view for schematically illustrating a third step of the method for manufacturing the silicon carbide semiconductor device according to the first embodiment of the present invention.

FIG. 10 is a schematic cross sectional view for schematically illustrating a fourth step of the method for manufacturing the silicon carbide semiconductor device according to the first embodiment of the present invention.

FIG. 11 is a schematic cross sectional view for schematically illustrating a fifth step of the method for manufacturing the silicon carbide semiconductor device according to the first embodiment of the present invention.

FIG. 12 is a schematic cross sectional view for schematically illustrating a sixth step of the method for manufacturing the silicon carbide semiconductor device according to the first embodiment of the present invention.

FIG. 13 is a schematic cross sectional view for schematically illustrating a seventh step of the method for manufacturing the silicon carbide semiconductor device according to the first embodiment of the present invention.

FIG. 14 is a schematic cross sectional view for schematically illustrating an eighth step of the method for manufacturing the silicon carbide semiconductor device according to the first embodiment of the present invention.

FIG. 15 is a schematic cross sectional view for schematically illustrating a ninth step of the method for manufacturing the silicon carbide semiconductor device according to the first embodiment of the present invention.

FIG. 16 is a schematic cross sectional view for schematically illustrating a structure of a silicon carbide semiconductor device according to a second embodiment of the present invention.

FIG. 17 is a schematic cross sectional view for schematically illustrating a first step of a method for manufacturing the silicon carbide semiconductor device according to the second embodiment of the present invention.

FIG. 18 is a schematic cross sectional view for schematically illustrating a second step of the method for manufacturing the silicon carbide semiconductor device according to the second embodiment of the present invention.

FIG. 19 is a schematic cross sectional view for schematically illustrating a third step of the method for manufacturing the silicon carbide semiconductor device according to the second embodiment of the present invention.

FIG. 20 is a schematic cross sectional view for schematically illustrating a structure of a silicon carbide semiconductor device according to a third embodiment of the present invention.

FIG. 21 is a schematic cross sectional view for schematically illustrating a method for manufacturing the silicon carbide semiconductor device according to the third embodiment of the present invention.

FIG. 22 is a schematic cross sectional view for schematically illustrating a structure of a silicon carbide semiconductor device according to a fourth embodiment of the present invention.

### DESCRIPTION OF EMBODIMENTS

### Description of Embodiments of the Present Invention

First, embodiments of the present invention are listed and described.

(1) A method for manufacturing a silicon carbide semiconductor device 1 according to one embodiment of the present invention includes the following steps. A silicon carbide substrate 10 is formed to have a first main surface 10a and a second main surface 10b opposite to first main surface 10a. The step of forming silicon carbide substrate 10 includes steps of: forming a first impurity region 12 having a first conductivity type by epitaxial growth; forming an embedded region 17 by performing ion implantation into first impurity region 12, embedded region 17 having a second conductivity type different from the first conductivity type, embedded region 17 being disposed cyclically; forming a second impurity region 13 by epitaxial growth, second impurity region 13 being in contact with first impurity region 12 and embedded region 17, second impurity region 13 having the second conductivity type, second impurity region 13 having an impurity concentration lower than an impurity concentration of embedded region 17; and forming a third impurity region 14 having the first conductivity type, third impurity region 14 being separated from first impurity region 12 by second impurity region 13. A trench TR is formed to have a side portion SW and a bottom portion BT, side portion SW extending to first impurity region 12 through second impurity region 13 and third impurity region 14, bottom portion BT being continuous to side portion SW, trench TR being disposed at the same cycle as embedded region 17. A gate insulating film 15 is formed in contact with first impurity region 12, second impurity region 13, and third impurity region 14 at side portion SW of trench TR.

In accordance with the method for manufacturing silicon carbide semiconductor device 1 according to (1), second impurity region 13 having an impurity concentration lower than that of embedded region 17 is formed in contact with first impurity region 12 and embedded region 17 by epitaxial growth after forming embedded region 17 by performing ion implantation into first impurity region 12. Accordingly, ion implantation energy can be reduced as compared with a case where embedded region 17 is formed by performing ion implantation via the surface of second impurity region 13 after forming second impurity region 13. As a result, flow of current can be suppressed from being hindered due to high ion implantation energy causing channeling and multiple scattering of ions and resulting in expansion of the impurity introduced by the ion implantation. Moreover, since the pn junction formed by first impurity region 12 and embedded region 17 is formed at a location deep and distant from first main surface 10a of silicon carbide substrate 10, electric field in trench TR can be shielded effectively. Further, since second impurity region 13 serving as the channel is formed by epitaxial growth, a high-quality channel can be realized.

(2) Preferably in the method for manufacturing silicon carbide semiconductor device 1 according to (1), in the step of forming trench TR, trench TR is formed such that side portion SW of trench TR is separated from embedded region 17 by first impurity region 12. A distance is not less than 0.2 μm and not more than 5 μm between side portion SW of trench TR and the side surface of embedded region 17 facing side portion SW in a direction parallel to first main surface 10a. When a distance D between side portion SW of trench TR and the side surface of embedded region 17 is smaller than 0.2 μm, current can be prevented from being expanded from the channel, thereby increasing the on resistance. When distance D between side portion SW of trench TR and the side surface of embedded region 17 is larger than 5 μm, an effect of shielding the electric field in bottom portion BT of trench TR by embedded region 17 is decreased. Therefore, distance D between side portion SW of trench TR and the side surface of embedded region 17 facing side portion SW is preferably not less than 0.2 μm and not more than 5 μm in the direction parallel to first main surface 10a of silicon carbide substrate 10.

(3) Preferably in the method for manufacturing silicon carbide semiconductor device 1 according to (1), in the step of forming trench TR, trench TR is formed to expose embedded region 17 at bottom portion BT of trench TR. Accordingly, bottom portion BT of trench TR can be effectively shielded from high electric field, thereby improving the breakdown voltage.

(4) Preferably in the method for manufacturing silicon carbide semiconductor device 1 according to (3), a width of bottom portion BT of trench TR is larger than a width of embedded region 17 in a direction parallel to first main surface 10a. Accordingly, flow of current can be suppressed from being hindered by a depletion layer expanding from the side surface of embedded region 17. As a result, the on resistance can be reduced.

(5) Preferably in the method for manufacturing silicon carbide semiconductor device 1 according to any one of (1) to (4), a depth H1 of trench TR in a normal direction of first main surface 10a is not less than 0.3 μm and not more than 3 μm, and is smaller than a width of trench TR in a direction parallel to first main surface 10a. When trench TR has a depth H1 of less than 0.3 μm, it becomes difficult to form a channel. When depth H1 of trench TR is more than 3 μm, it becomes difficult to control the shape of the trench. Hence, depth H1 of trench TR is preferably not less than 0.3 μm and not more than 3 μm.

(6) Preferably in the method for manufacturing silicon carbide semiconductor device 1 according to any one of (1) to (5), the first main surface of the silicon carbide substrate corresponds to a plane angled off relative to a {0001} plane in an off direction. Side portion SW of trench TR includes a plane SW1 having a plane orientation perpendicular to the off direction and perpendicular to a normal direction of first main surface 10a. Since the side wall of the trench is mainly constituted of a plane having a line normal to the off direction, deviation of the plane orientation of the side wall can become minimum. Moreover, when the off direction is, for example, the <11-20> direction, flatter silicon carbide epitaxial layer 5 can be formed.

(7) Preferably in the method for manufacturing silicon carbide semiconductor device 1 according to any one of (1) to (6), in the step of forming embedded region 17, the ion implantation is performed in a direction perpendicular to the off direction and inclined from the normal direction of first main surface 10a by not less than 2° and not more than 10° relative to a direction parallel to first main surface 10a. By performing ion implantation in the direction perpendicular to the off direction and inclined by not less than 2° and not more than 10° relative to the direction parallel to first main surface 10a, channeling can be suppressed effectively. Moreover, when forming embedded region 17 at corner portion CR of bottom portion BT of trench TR at which the breakdown voltage is likely to be deteriorated, occurrence of location deviation of embedded region 17 can be suppressed effectively.

(8) Preferably in the method for manufacturing the silicon carbide semiconductor device 1 according to any one of (1) to (7), in the step of forming trench TR, when viewed from the normal direction of first main surface 10a, trench TR is formed such that a corner portion CR of bottom portion BT of trench TR overlaps with embedded region 17. Accordingly, it is possible to shield an electric field at corner portion CR of bottom portion BT of trench TR at which the breakdown voltage is likely to be deteriorated.

(9) Preferably in the method for manufacturing silicon carbide semiconductor device 1 according to any one of (1) to (8), the step of forming silicon carbide substrate 10 further includes a step of forming a carrier injection region 28 by performing ion implantation into first impurity region 12 from the second main surface 10b side, carrier injection region 28 having the second conductivity type, carrier injection region 28 being disposed cyclically. Accordingly, injection of carriers from carrier injection region 28 can be facilitated, thereby reducing on resistance.

(10) A silicon carbide semiconductor device 1 according to one embodiment of the present invention includes a silicon carbide substrate 10 and a gate insulating film 15. Silicon carbide substrate 10 has a first main surface 10a and a second main surface 10b opposite to first main surface 10a. Silicon carbide substrate 10 includes a first impurity region 12, a second impurity region 13, a third impurity region 14, and an embedded region 17, first impurity region 12 having a first conductivity type, second impurity region 13 being in contact with first impurity region 12, second impurity region 13 having a second conductivity type different from the first conductivity type, third impurity region 14 having the first conductivity type, third impurity region 14 being separated from first impurity region 12 by second impurity region 13, embedded region 17 having the second conductivity type, embedded region 17 having an impurity concentration higher than an impurity concentration of second impurity region 13, embedded region 17 extending from a portion of an end portion of second impurity region 13 at the second main surface 10b side toward second main surface 10b. A trench TR is formed in first main surface 10a of silicon carbide substrate 10 to have a side portion SW and a bottom portion BT, side portion SW being continuous to first main surface 10a, bottom portion BT being continuous to side portion SW. Gate insulating film 15 is in contact with first impurity region 12, second impurity region 13, and third impurity region 14 at side portion SW of trench TR and in contact with first impurity region 12 at bottom portion BT of trench TR. Embedded region 17 has locations each having an impurity concentration four times as large as an impurity concentration of second impurity region 13, a distance being not more than 0.3 μm from a location closest to second impurity region 13 among the locations to a boundary portion between second impurity region 13 and embedded region 17 in a normal direction of first main surface 10a. This provides an effect of sufficiently shielding electric field by embedded region 17 to reduce a capacitance of the source portion.

(11) Preferably in silicon carbide semiconductor device 1 according to (10), when viewed in the normal direction of first main surface 10a, a corner portion CR of bottom portion BT of trench TR is disposed to overlap with embedded region 17. Accordingly, it is possible to shield an electric field at corner portion CR of bottom portion BT of trench TR at which the breakdown voltage is likely to be deteriorated.

(12) Preferably in silicon carbide semiconductor device 1 according to (10) or (11), first impurity region 12 has a first region 12a, a second region 12b, and a third region 12c, first region 12a being in contact with second impurity region 13, second region 12b being in contact with first region 12a, second region 12b being located opposite to second impurity region 13 when viewed from first region 12a, second region 12b having an impurity concentration higher than an impurity concentration of first region 12a, third region 12c being in contact with second region 12b, third region 12c being located opposite to first region 12a when viewed from second region 12b, third region 12c having an impurity concentration lower than the impurity concentration of second region 12b. In this way, during off time, a depletion layer is expanded in first region 12a having a low impurity concentration to relax electric field in trench TR, whereby a high breakdown voltage can be maintained. During on time, with voltage applied to gate electrode 27, carriers can be gathered around trench TR from second region 12b having a high impurity concentration. As a result, high conductivity can be realized, thus reducing on resistance. That is, on resistance can be reduced and breakdown voltage can be improved.

(13) Preferably in silicon carbide semiconductor device 1 according to any one of (10) to (12), silicon carbide substrate 10 further includes a second conductivity type epitaxial layer 29 and a carrier injection region 28, second conductivity type epitaxial layer 29 having the second conductivity type, second conductivity type epitaxial layer 29 constituting second main surface 10b, second conductivity type epitaxial layer 29 being provided in contact with first impurity region 12, carrier injection region 28 having the second conductivity type, carrier injection region 28 being in contact with second conductivity type epitaxial layer 29 and first impurity region 12, carrier injection region 28 having an impurity concentration higher than an impurity concentration of second conductivity type epitaxial layer 29, carrier injection region 28 being provided cyclically. Accordingly, injection of carriers from carrier injection region 28 can be facilitated, thereby reducing on resistance.

### Details of Embodiments of the Present Invention

The following describes embodiments of the present invention with reference to figures. It should be noted that in the below-mentioned figures, the same or corresponding portions are given the same reference characters and are not described repeatedly. Regarding crystallographic indications in the present specification, an individual orientation is represented by [ ], a group orientation is represented by < >, and an individual plane is represented by ( ), and a group plane is represented by { }. In addition, a negative index is supposed to be crystallographically indicated by putting “-” (bar) above a numeral, but is indicated by putting the negative sign before the numeral in the present specification.

### First Embodiment

First, the following describes a configuration of a MOSFET serving as a silicon carbide semiconductor device according to a first embodiment of the present invention. With reference to FIG. 1, a MOSFET 1 according to the first embodiment mainly includes a silicon carbide substrate 10, a gate electrode 27, a gate insulating film 15, an interlayer insulating film 21, a source electrode 16, a source interconnection 19, a drain electrode 20, and a protective film 24. Silicon carbide substrate 10 has a first main surface 10a and a second main surface 10b opposite to first main surface 10a, and mainly includes a silicon carbide single crystal substrate 11 and a silicon carbide epitaxial layer 5 provided on silicon carbide single crystal substrate 11.

Silicon carbide single crystal substrate 11 is composed of hexagonal silicon carbide single crystal of polytype 4H, for example. First main surface 10a of silicon carbide substrate 10 has a maximum diameter of, for example, 150 mm, and preferably has a maximum diameter of not less than 150 mm. First main surface 10a of silicon carbide substrate 10 corresponds to a {0001} plane or a plane angled off by not more than 8° relative to the {0001} plane, for example. Silicon carbide single crystal substrate 11 has a thickness of 400 μm, for example. Silicon carbide single crystal substrate 11 has a resistivity of 0.017 Ωcm, for example.

Silicon carbide epitaxial layer 5 mainly has a first impurity region 12, a base region 13 (second impurity region 13), a source region 14 (third impurity region 14), a contact region 18, an embedded region 17, and a buffer layer 22. Buffer layer 22 is provided on silicon carbide single crystal substrate 11. First impurity region 12 is provided on buffer layer 22. Each of first impurity region 12 and buffer layer 22 is an n type (first conductivity type) region including an n type impurity (donor) for providing n type conductivity, such as nitrogen. First impurity region 12 is in contact with base region 13 and embedded region 17.

The concentration of the n type impurity in first impurity region 12 such as nitrogen and the thickness of first impurity region 12 are changed depending on the breakdown voltage. When the breakdown voltage is 1200 V, the thickness of first impurity region 12 is about 10 μm and the nitrogen concentration in first impurity region 12 is about 1×10¹⁶ cm³, for example. Moreover, when the breakdown voltage is 1700 V, the thickness of first impurity region 12 is about 20 μm and the nitrogen concentration in first impurity region 12 is about 5×10¹⁵ cm⁻³, for example. Further, when the breakdown voltage is 3300 V, the thickness of first impurity region 12 is about 30 μm and the nitrogen concentration in first impurity region 12 is about 3×10¹⁵ cm⁻³, for example.

Preferably, the concentration of the n type impurity in buffer layer 22 such as nitrogen is lower than the concentration of the n type impurity in silicon carbide single crystal substrate 11 such as nitrogen. The concentration of the n type impurity in silicon carbide single crystal substrate 11 such as nitrogen is not less than 5×10¹⁸ cm⁻³ and not more than 9×10¹⁸ cm⁻³, for example. The concentration of the n type impurity in buffer layer 22 such as nitrogen is not less than 1×10¹⁸ cm⁻³ and not more than 2×10¹⁸ cm⁻³, for example. Preferably, the concentration of the n type impurity in first impurity region 12 such as nitrogen is lower than the concentration of the n type impurity in buffer layer 22 such as nitrogen.

Base region 13 (second impurity region 13) is provided on each of first impurity region 12 and embedded region 17 in contact with first impurity region 12. Base region 13 is a region having p type conductivity (second conductivity type) different from n type conductivity. Base region 13 includes a p type impurity (acceptor) for providing p type conductivity, such as Al (aluminum) or B (boron). The concentration of the p type impurity in base region 13 such as aluminum is 7×10¹⁵ cm⁻³, for example. Base region 13 is an epitaxial layer formed by epitaxial growth, for example. Base region 13 has a thickness of 0.5 μm, for example.

Source region 14 (third impurity region 14) is provided on base region 13 to be separated from first impurity region 12 by base region 13. Source region 14 includes an n type impurity for providing n type conductivity such as phosphorus, and therefore has n type conductivity. The concentration of the n type impurity in source region 14 is higher than the concentration of the n type impurity in first impurity region 12. The concentration of the n type impurity in source region 14 such as phosphorus is 1×10²⁰ cm⁻³, for example.

Contact region 18 is a p type region including a p type impurity such as aluminum or boron. Contact region 18 is provided to be interposed by source region 14 and base region 13 so as to extend to embedded region 17 through each of source region 14 and base region 13. In other words, contact region 18 is formed to connect first main surface 10a of silicon carbide substrate 10 to embedded region 17. The concentration of the p type impurity in contact region 18 is higher than the concentration of the p type impurity in base region 13. The concentration of the p type impurity in contact region 18 such as aluminum is 1×10²⁰ cm⁻³, for example.

Embedded region 17 includes a p type impurity such as aluminum or boron, and therefore has p type conductivity. Embedded region 17 has an impurity concentration higher than that of base region 13. The concentration of the p type impurity in embedded region 17 such as aluminum is not less than 5×10¹⁷ cm⁻³ and not more than 8×10¹⁸ cm⁻³, for example. It should be noted that the elements and concentrations of the impurities in the above regions can be measured by SCM (Scanning Capacitance Microscope), SIMS (Secondary Ion Mass Spectrometry), or the like, for example.

Embedded region 17 is in contact with each of contact region 18 and base region 13. Embedded region 17 is provided to extend from a portion of end portion 13a of base region 13 at the second main surface 10b side of silicon carbide substrate 10 toward second main surface 10b. In other words, embedded region 17 is located opposite to source region 14 when viewed from base region 13 and is located opposite to source electrode 16 when viewed from contact region 18. The width of embedded region 17 may be larger than the width of contact region 18 in a direction parallel to first main surface 10a.

The end portion of embedded region 17 at the second main surface 10b side and the side portion of embedded region 17 are formed such that a portion of first impurity region 12 is interposed between two portions of embedded region 17 when viewed in a cross section (a field of view in the direction parallel to first main surface 10a of silicon carbide substrate 10, i.e., a field of view of FIG. 1).

In first main surface 10a of silicon carbide substrate 10, trenches TR are formed to each have (i) a side portion SW continuous to first main surface 10a and (ii) a bottom portion BT continuous to side portion SW. Side portion SW of trench TR extends to first impurity region 12 through each of source region 14 and base region 13, and bottom portion BT of trench TR is located in first impurity region 12. That is, first impurity region 12, base region 13, and source region 14 are in contact with side portion SW of the trench, and first impurity region 12 is in contact with bottom portion BT of trench TR. Side portion SW of trench TR extends in a direction substantially parallel to the normal direction of first main surface 10a of silicon carbide substrate 10, and bottom portion BT of trench TR is substantially parallel to first main surface 10a of silicon carbide substrate 10. A boundary between side portion SW and bottom portion BT of trench TR may be formed to have a curvature. Embedded region 17 is provided to face a corner portion at which side portion SW and bottom portion BT of trench TR are in contact with each other. Bottom portion BT of trench TR is located at the second main surface 10b side relative to a plane along the end portion of embedded region 17 at the first main surface 10a side, and is located at the first main surface 10a side relative to a plane along the end portion of embedded region 17 at the second main surface 10b side.

When trench TR has a depth H1 of less than 0.3 μm, it becomes difficult to form a channel. When depth H1 of trench TR is more than 3 μm, it becomes difficult to control the shape of the trench. Hence, depth H1 of trench TR is preferably not less than 0.3 μm and not more than 3 μm. More preferably, depth H1 of trench TR is not less than 0.3 μm and not more than 2 μm. Further preferably, depth H1 of trench TR is not less than 0.8 μm and not more than 1.5 μm. Preferably, depth H1 of trench TR is smaller than the width of trench TR. When depth H1 of trench TR is smaller than the width of trench TR, gate insulating film 15 having a uniform thickness can be formed readily in contact with side portion SW and bottom portion BT of trench TR.

When a distance D between side portion SW of trench TR and the side surface of embedded region 17 is smaller than 0.2 μm, current can be prevented from being expanded from the channel, thereby increasing on resistance. When distance D between side portion SW of trench TR and the side surface of embedded region 17 is larger than 5 μm, an effect of shielding the electric field in bottom portion BT of trench TR by embedded region 17 is decreased. Therefore, distance D between side portion SW of trench TR and the side surface of embedded region 17 facing side portion SW is preferably not less than 0.2 μm and not more than 5 μm in the direction parallel to first main surface 10a of silicon carbide substrate 10. More preferably, distance D between side portion SW of trench TR and the side surface of embedded region 17 facing side portion SW is not less than 1 μm and not more than 2 μm.

As described above, a channel for securing breakdown voltage is formed in a JFET region sandwiched by the pn junction provided by first impurity region 12 having the n type region and embedded region 17 having p type conductivity. In base region 13 in contact with side portion SW of trench TR, a channel for current control is formed. A direction in which current flows in the channel for current control is substantially the same as a direction in which current flows in the JFET region, whereby current is controlled at gate electrode 27 in contact with gate insulating film 15 and the breakdown voltage is secured in the JFET region.

Gate insulating film 15 is composed of silicon dioxide and is provided in contact with side portion SW and bottom portion BT of trench TR, for example. Gate insulating film 15 is in contact with first impurity region 12, base region 13, and source region 14 at side portion SW of trench TR, and is in contact with first impurity region 12 at bottom portion BT of trench TR. Gate insulating film 15 is configured such that a channel region CH can be formed at base region 13 that is in contact with gate insulating film 15.

Gate electrode 27 is disposed in contact with gate insulating film 15, and is provided to fill a groove formed by gate insulating film 15. Gate electrode 27 may be provided to be exposed through source region 14. Gate electrode 27 is composed of a conductor such as polysilicon doped with an impurity, for example.

Source electrode 16 is composed of a material including Ni and Ti, for example. Source electrode 16 is in contact with each of source region 14 and contact region 18 at first main surface 10a of silicon carbide substrate 10. Source electrode 16 includes an alloy layer in ohmic junction with source region 14. The alloy layer is a silicide of a metal included in source electrode 16, for example. Preferably, source electrode 16 is composed of a material including Ti, Al, and Si.

Interlayer insulating film 21 is provided at a location facing first main surface 10a of silicon carbide substrate 10. Specifically, interlayer insulating film 21 is provided in contact with each of gate electrode 27 and gate insulating film 15 to cover gate electrode 27. Interlayer insulating film 21 includes a TEOS (Tetra Ethyl Ortho Silicate) oxide film and a PSG (Phosphorus Silicon Glass), for example. Interlayer insulating film 21 electrically insulates gate electrode 27 from source electrode 16. Source interconnection 19 is provided in contact with source electrode 16 to cover interlayer insulating film 21. Source interconnection 19 is electrically connected to source region 14 via source electrode 16. Source interconnection 19 is composed of a material including AlSiCu, for example. Protective film 24 is provided on source interconnection 19 to cover source interconnection 19. Protective film 24 includes a nitride film and polyimide, for example.

Drain electrode 20 is provided in contact with second main surface 10b of silicon carbide substrate 10. This drain electrode 20 is composed of a material capable of ohmic junction with n type silicon carbide single crystal substrate 11, such as NiSi (nickel silicide). Accordingly, drain electrode 20 is electrically connected to silicon carbide single crystal substrate 11.

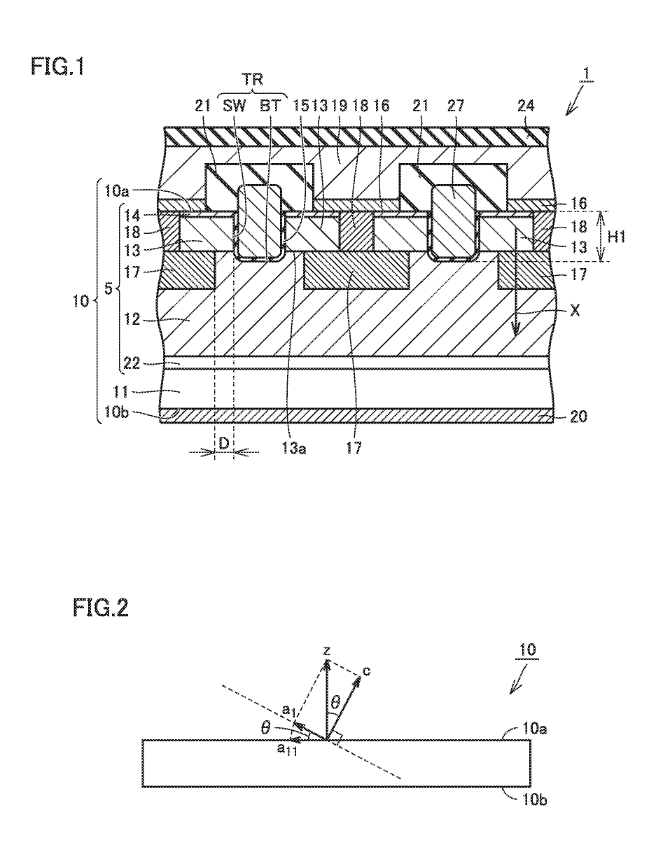

With reference to FIG. 2, the following describes a plane orientation of silicon carbide substrate 10. First main surface 10a of silicon carbide substrate 10 corresponds to a plane angled off by an off angle θ in an off direction a1 relative to a {0001} plane (plane indicated by a broken line), for example. The off direction is a direction in which a normal line vector z of first main surface 10a is inclined relative to a [0001] direction. In FIG. 2, a direction c is the [0001] direction (i.e., c axis of the hexagonal silicon carbide), and off direction al is a <11-20> direction, for example. Off angle θ is preferably an angle of not more than 8°. An in-plane off direction is a direction obtained by projecting the off direction onto first main surface 10a. In the case of FIG. 2, the in-plane off direction is an all direction. An angle formed between off direction al and in-plane off direction all is equal to off angle θ. It should be noted that off direction al is not limited to the <11-20> direction, for example. Off direction al may be a <1-100> direction, for example.

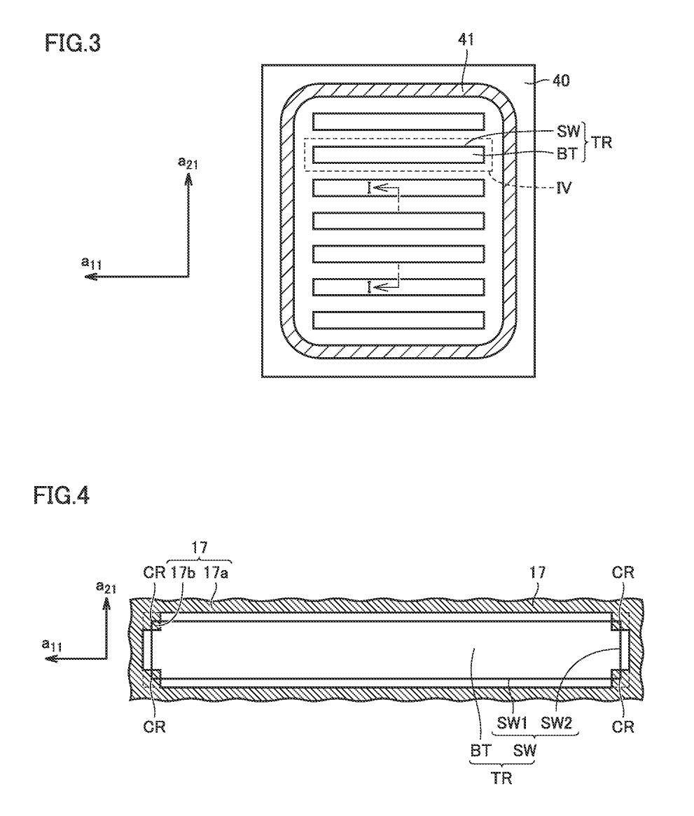

With reference to FIG. 3, the following describes planar structures of trenches TR formed in a semiconductor chip 40. It should be noted that FIG. 1 is a cross sectional view when viewed in a region I-I in FIG. 3. That is, a direction perpendicular to the plane of sheet of FIG. 1 corresponds to in-plane off direction a11. When viewed in a plan view (field of view in a normal direction of first main surface 10a of silicon carbide substrate 10), bottom portion BT of each trench TR has a rectangular shape, for example. The long side direction of the rectangle is the same as in-plane off direction all, for example. In-plane off direction all is, for example, a direction obtained by projecting the <11-20> direction onto first main surface 10a, and including a component of the <11-20> direction. The short side direction of the rectangle is a direction a21 parallel to first main surface 10a and perpendicular to in-plane off direction a11. Direction a21 is the <1-100> direction, for example. Semiconductor chip 40 may include: the plurality of trenches TR disposed side by side in the short side direction of each of trenches TR; and a guard ring 41 surrounding the plurality of trenches TR. Trenches TR are cyclically disposed in the <1-100> direction, for example.

FIG. 4 is an enlarged view of a region IV in FIG. 3. As shown in FIG. 4, side portion SW of trench TR includes a first side portion SW1 and a second side portion SW2. First side portion SW1 of trench TR corresponds to a plane having a plane orientation of direction a21 perpendicular to off direction a1 and perpendicular to the normal direction of first main surface 10a. First side portion SW1 corresponds to a (1-100) plane having a normal line in the <1-100> direction, for example. Second side portion SW2 of trench TR corresponds to a plane having a plane orientation of in-plane off direction a11. Second side portion SW2 corresponds to a plane having a normal line including a component of the <11-20> direction, for example.

With reference to FIG. 4, embedded region 17 may include a first embedded region 17a and second embedded regions 17b. When viewed in a plan view, first embedded region 17a is formed to surround the entire side portion SW of trench TR. When viewed in a plan view, second embedded regions 17b are disposed to overlap with four corner portions CR of bottom portion BT of trench TR. In other words, when viewed in the normal direction of first main surface 10a, embedded region 17 is disposed to overlap with corner portions CR of bottom portion BT of trench TR, and is disposed outside bottom portion BT not to overlap with bottom portion BT in a region between two adjacent corner portions CR.

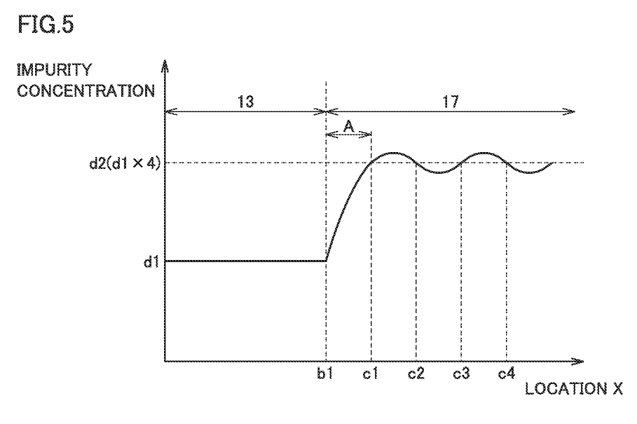

With reference to FIG. 5, the following describes a distribution of the impurity concentration in each of base region 13 and embedded region 17. Each of base region 13 and embedded region 17 includes a p type impurity such as aluminum, for example. An impurity concentration d1 of the p type impurity in base region 13 is lower than the maximum value of an impurity concentration of the p type impurity in embedded region 17. Since base region 13 is an impurity region formed by epitaxial growth, the impurity concentration in base region 13 is substantially constant in the normal direction of first main surface 10a (i.e., a direction of arrow X in FIG. 1). Since embedded region 17 is an impurity region formed by multiple ion implantations, embedded region 17 has a plurality of maximum values in the direction along the normal direction of first main surface 10a. In embedded region 17, each of locations c1, c2, c3, c4 has an impurity concentration d2(=d1×4) four times as large as impurity concentration d1 of base region 13. A distance A is not more than 0.3 μm from (i) location c1 closest to base region 13 among locations c1, c2, c3, c4 to (ii) a boundary portion b1 between base region 13 and embedded region 17 in the normal direction of first main surface 10a.

Next, the following describes an operation of MOSFET 1 according to the first embodiment. With reference to FIG. 1, when a voltage is applied between source electrode 16 and drain electrode 20 while an applied voltage to gate electrode 27 is lower than a threshold voltage, i.e., while it is in off state, a pn junction formed between base region 13 and first impurity region 12 is reverse-biased. Accordingly, MOSFET 1 is in the non-conductive state. On the other hand, when gate electrode 27 is fed with a voltage equal to or greater than the threshold voltage, an inversion layer is formed in a channel region near a location at which base region 13 makes contact with gate insulating film 15. As a result, source region 14 and first impurity region 12 are electrically connected to each other, whereby a current flows between source electrode 16 and drain electrode 20. In the manner described above, MOSFET 1 operates.

Next, the following describes a method for manufacturing MOSFET 1 serving as the silicon carbide semiconductor device according to the first embodiment.

With reference to FIG. 7, a silicon carbide single crystal ingot grown by, for example, a Modified-Lely method is sliced to obtain a substrate, and a surface of the substrate is mirror-polished, thereby preparing silicon carbide single crystal substrate 11. Silicon carbide single crystal substrate 11 is hexagonal silicon carbide of polytype 4H, for example. The main surface of silicon carbide single crystal substrate 11 has a diameter of 150 mm, and has a thickness of 400 μm. The main surface of silicon carbide single crystal substrate 11 corresponds to a {0001} plane or a plane angled off by about not more than 8° relative to the {0001} plane, for example.

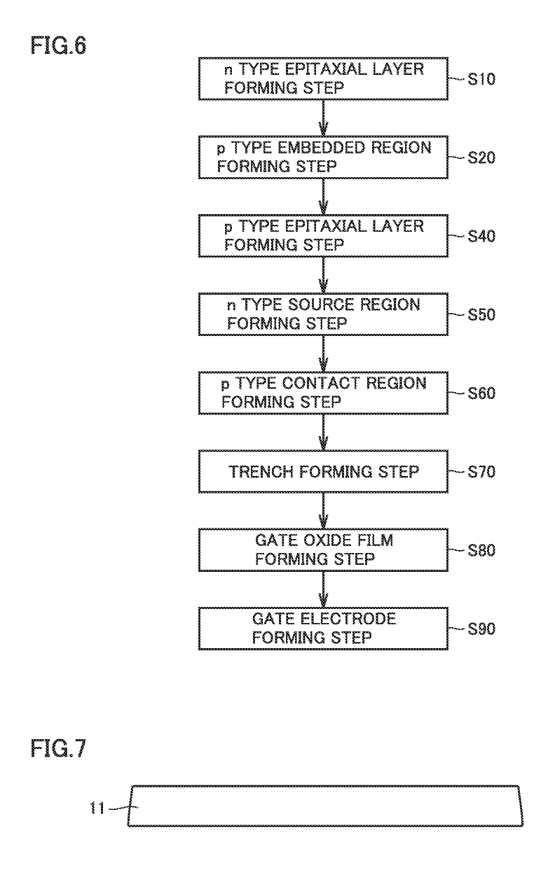

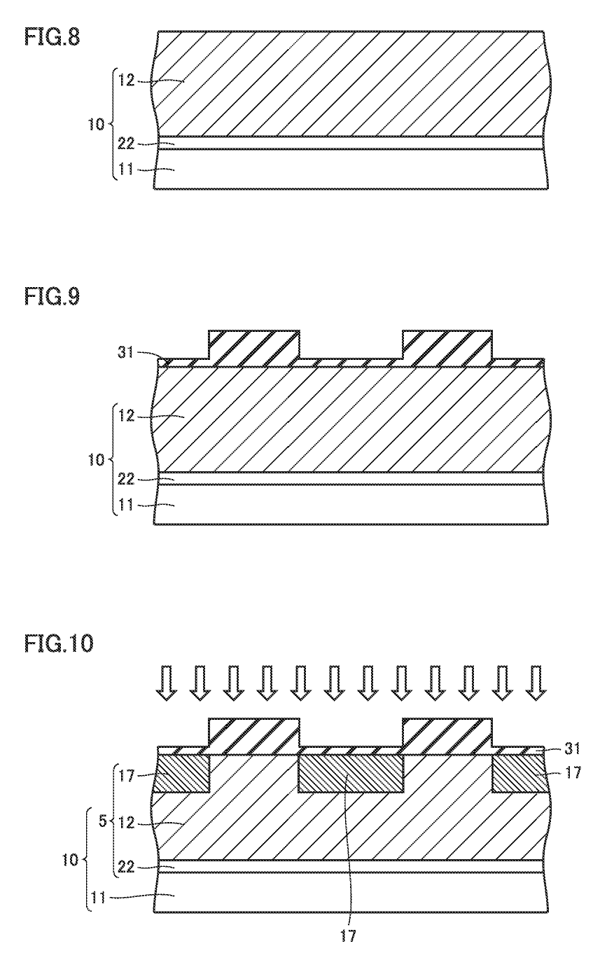

Next, an n type epitaxial layer forming step (S10: FIG. 6) is performed. For example, silicon carbide single crystal substrate 11 is supplied with (i) a carrier gas including hydrogen, (ii) a source material gas including silane and propane, and (iii) a dopant gas including nitrogen. Under a pressure of 100 mbar (10 kPa), silicon carbide single crystal substrate 11 is heated to about 1550° C., for example. Accordingly, as shown in FIG. 8, silicon carbide epitaxial layer 5 having n type conductivity is formed on silicon carbide single crystal substrate 11. Silicon carbide epitaxial layer 5 has buffer layer 22 formed on silicon carbide single crystal substrate 11, and first impurity region 12 formed on buffer layer 22. First impurity region 12 is doped with nitrogen, and has a nitrogen concentration of 1.0×10¹⁶ cm⁻², for example. First impurity region 12 has a thickness of 10 μm, for example. As described above, first impurity region 12 having n type conductivity is formed by epitaxial growth.

Next, a p type embedded region forming step (S20: FIG. 6) is performed. Specifically, with reference to FIG. 9, an ion implantation mask 31 is formed on first impurity region 12 of silicon carbide epitaxial layer 5. The ion implantation mask is composed of a material including a TEOS oxide film, and ion implantation mask 31 has a thickness of 1.6 μm, for example. Next, RF (Radio Frequency) etching is performed onto ion implantation mask 31 using CHF₃ and O₂. Accordingly, a through film of about 80 nm is left at a portion to be subjected to ion implantation, for example. Next, using ion implantation mask 31 having the through film, ion implantation is performed into first impurity region 12 of silicon carbide epitaxial layer 5. For example, Al (aluminum) ions are implanted into silicon carbide epitaxial layer 5 through the through film in a direction of arrows, thereby forming embedded region 17 each having p type conductivity and an impurity concentration higher than that of base region 13 (see FIG. 10). When viewed in a cross section, embedded region 17 has a plurality of portions disposed with an interval therebetween. Specifically, embedded region 17 is disposed cyclically in the direction parallel to first main surface 10a of silicon carbide substrate 10 and along direction a21 (see FIG. 3).

Ion implantation conditions, such as acceleration voltage and dose amount, are adjusted such that the impurity concentration of embedded region 17 at the second main surface 10b side becomes higher than the impurity concentration of embedded region 17 at the first main surface 10a side. Preferably, in the step of forming embedded region 17, for example, aluminum ions are implanted in a direction perpendicular to off direction a1 and inclined from the normal direction of first main surface 10a by not less than 2° and not more than 10° relative to the direction parallel to first main surface 10a. The direction perpendicular to off direction a1 and parallel to first main surface 10a is the <1-100> direction, for example. By performing the ion implantation into first impurity region 12 as described above, embedded region 17 is formed to have p type conductivity different from n type conductivity and to be disposed cyclically.

Next, a p type epitaxial layer forming step (S40: FIG. 6) is performed. Specifically, base region 13 having p type conductivity and doped with aluminum at an impurity concentration of, for example, 7×10¹⁵ cm⁻³ is formed by epitaxial growth. The base region is formed in contact with embedded region 17 and first impurity region 12 by epitaxial growth (see FIG. 11). Base region 13 has a thickness of 0.5 μm, for example. As described above, base region 13 is formed by epitaxial growth in contact with first impurity region 12 and embedded region 17 to have p type conductivity and have an impurity concentration lower than that of embedded region 17.

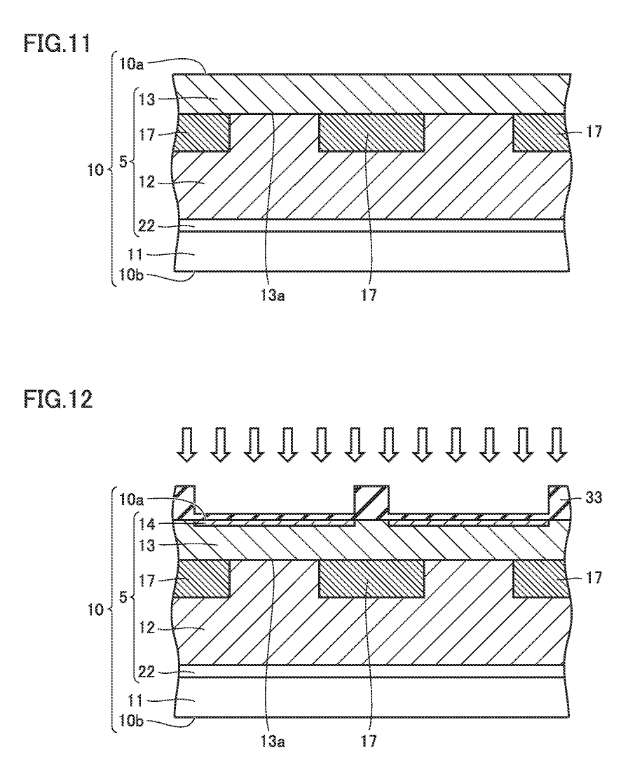

Next, an n type source region forming step (S50: FIG. 6) is performed. With reference to FIG. 12, an ion implantation mask 33 is formed on base region 13. The ion implantation mask is composed of a material including a TEOS oxide film, and ion implantation mask 31 has a thickness of 1.6 μm, for example. Next, RF etching is performed onto ion implantation mask 33 using CHF₃ and O₂. Accordingly, a through film of about 80 nm is left above a region to be provided with source region 14, for example. Next, ion implantation mask 33 having the through film is employed to perform ion implantation into base region 13 of silicon carbide epitaxial layer 5. For example, P (phosphorus) ions are implanted into base region 13 of silicon carbide epitaxial layer 5 through the through film in the direction of arrows, thereby forming source region 14 having n type conductivity (see FIG. 12). Preferably in the step of forming source region 14, for example, phosphorous ions are implanted in the direction perpendicular to off direction al and inclined from the normal direction of first main surface 10a by not less than 2° and not more than 10° relative to the direction parallel to first main surface 10a. The direction perpendicular to off direction al and parallel to first main surface 10a is the <1-100> direction, for example. In this way, source region 14 having n type conductivity is formed to be separated from first impurity region 12 by base region 13.

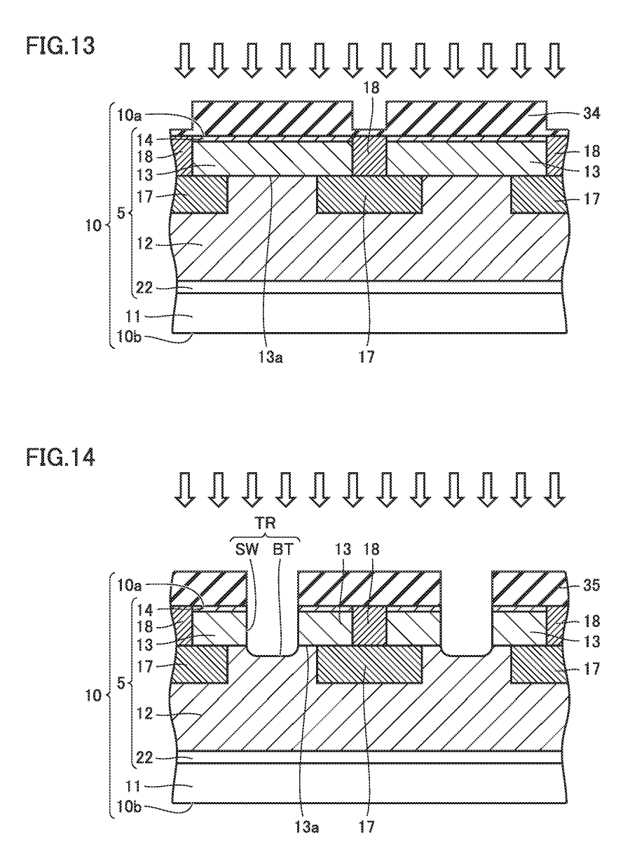

Next, a p type contact region forming step (S60: FIG. 6) is performed. With reference to FIG. 13, an ion implantation mask 34 is formed on base region 13 and source region 14. The ion implantation mask is composed of a material including a TEOS oxide film, and ion implantation mask 31 has a thickness of 1.6 μm, for example. Next, RF etching is performed onto ion implantation mask 34 using CHF₃ and O₂. Accordingly, a through film of about 80 nm is left above a region to be provided with contact region 18, for example. Next, ion implantation mask 34 having the through film is employed to perform ion implantation into base region 13 of silicon carbide epitaxial layer 5. For example, aluminum ions are implanted deep into base region 13 to reach embedded region 17. Accordingly, contact region 18 having p type conductivity is formed to be interposed by source region 14 and by base regions 13 and to connect first main surface 10a of silicon carbide substrate 10 to embedded region 17 (see FIG. 13). Preferably in the step of forming contact region 18, for example, aluminum ions are implanted in the direction perpendicular to off direction a1 and inclined from the normal direction of first main surface 10a by not less than 2° and not more than 10° relative to the direction parallel to first main surface 10a. The direction perpendicular to off direction al and parallel to first main surface 10a is the <1-100> direction, for example.

Next, an activation annealing step is performed. Ion implantation mask 34 is removed from first main surface 10a of silicon carbide substrate 10, and then first main surface 10a of silicon carbide substrate 10 is covered with a protective film. Next, under an argon atmosphere, silicon carbide substrate 10 is heated for about 30 minutes at a temperature of not less than 1650° C. and not more than 1750° C., for example. This activates: the p type impurity in base region 13 such as aluminum; the n type impurity in source region 14 such as phosphorus; and the p type impurity in contact region 18 such as aluminum.

Next, a trench forming step (S70: FIG. 6) is performed. With reference to FIG. 14, an etching mask 35 is formed on source region 14 and contact region 18. Etching mask 35 is composed of a material including a TEOS oxide film, and etching mask 35 has a thickness of 1.6 μm, for example. Next, CHF₃ and O₂ are used to perform RF etching onto etching mask 35 on regions to be provided with trenches TR, thereby forming openings in etching mask 35. Next, etching is performed onto silicon carbide substrate 10 using etching mask 35 thus provided with the openings above the regions to be provided with trenches TR. For example, SF₆ and O₂ are used to perform ECR (Electron Cyclotron Resonance) plasma etching onto silicon carbide substrate 10. Accordingly, trenches TR are formed to each have (i) side portion SW continuous to first main surface 10a of silicon carbide substrate 10 and (ii) bottom portion BT continuous to side portion SW. Source region 14, base region 13, and first impurity region 12 are exposed at side portion SW of trench TR, and first impurity region 12 is exposed at bottom portion BT of trench TR.

With reference to FIG. 3 and FIG. 14, the cycle of trenches TR in direction a21 is the same as the cycle of embedded region 17 in direction a2. The expression “the cycle of trenches TR is the same as the cycle of embedded region 17” means that an interval between two adjacent trenches TR is substantially the same as an interval between two adjacent embedded regions 17, and may include an alignment error or the like. In other words, one embedded region 17 corresponding to one trench TR may be provided. In this way, trenches TR are formed to each have (i) side portion SW extending to first impurity region 12 through base region 13 and source region 14 and (ii) bottom portion BT continuous to side portion SW, and to be disposed at the same cycle as embedded region 17.

Preferably, in the step of forming trenches TR, each of trenches TR is formed such that side portion SW of trench TR is separated from embedded region 17 by first impurity region 12. Distance D (see FIG. 1) between side portion SW of trench TR and the side surface of embedded region 17 facing side portion SW is not less than 0.2 μm and not more than 5 μm in the direction parallel to first main surface 10a of silicon carbide substrate 10. Preferably, depth H of trench TR in the normal direction of first main surface 10a of silicon carbide substrate 10 is not less than 0.3 μm and not more than 3 μm, and is smaller than the width of trench TR in the direction parallel to first main surface 10a of silicon carbide substrate 10.

Preferably, first main surface 10a of silicon carbide substrate 10 is a plane angled off relative to the {0001} plane in off direction a1. As shown in FIG. 4, side portion SW of trench TR includes first side portion SW1 and second side portion SW2. First side portion SW1 of trench TR is a plane having the plane orientation of direction a21 perpendicular to off direction a1 and perpendicular to the normal direction of first main surface 10a. Second side portion SW2 of trench TR corresponds to a plane having the plane orientation of in-plane off direction a11.

Preferably, in the step of forming trenches TR, when viewed in the normal direction of first main surface 10a, each of trenches TR is formed such that corner portion CR of bottom portion BT of trench TR overlaps with embedded region 17. With reference to FIG. 4, embedded region 17 may include first embedded region 17a and second embedded regions 17b. When viewed in a plan view, first embedded region 17a is formed to surround the entire side portion SW of trench TR. When viewed in a plan view, second embedded regions 17b are formed to overlap with four corner portions CR of bottom portion BT of trench TR. In other words, when viewed in the normal direction of first main surface 10a, trench TR is formed such that embedded region 17 is disposed to overlap with corner portions CR of bottom portion BT of trench TR and is disposed outside bottom portion BT not to overlap with bottom portion BT at the region interposed between two adjacent corner portions CR.

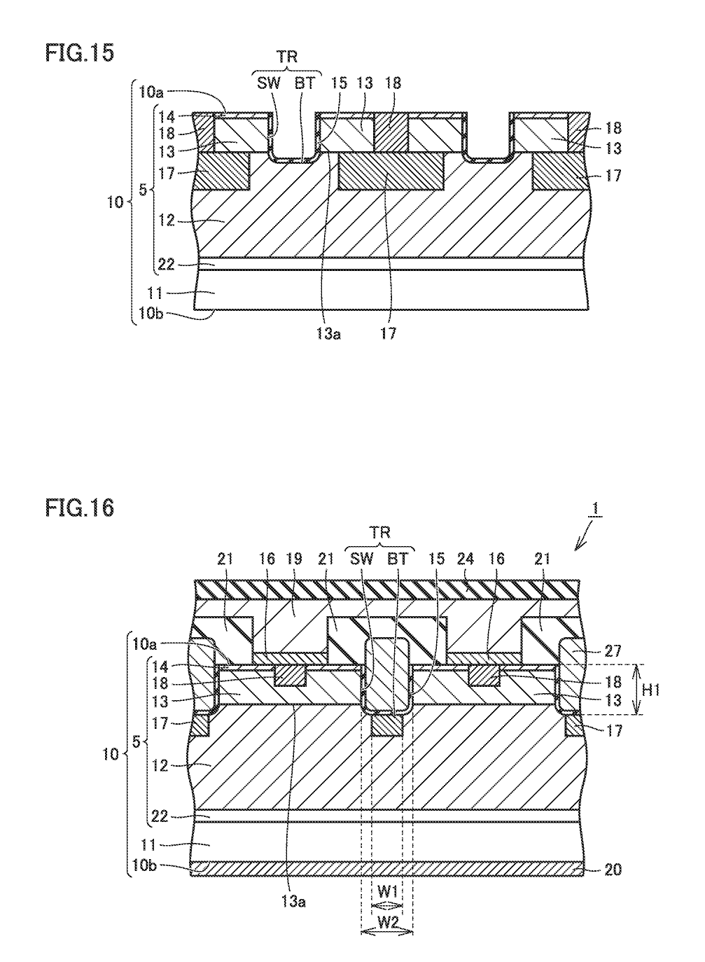

Next, a gate oxide film forming step (S80: FIG. 6) is performed. Specifically, silicon carbide substrate 10 having first main surface 10a provided with trench TR is placed in a heating furnace. Oxygen is introduced to the heating furnace to perform dry oxidation of silicon carbide substrate 10 at a temperature of, for example, not less than 1100° C. and not more than 1200° C., thereby forming gate insulating film 15 in contact with side portion SW and bottom portion BT of trench TR. Gate insulating film 15 is in contact with first impurity region 12, base region 13, and source region 14 at side portion SW of trench TR, and is in contact with first impurity region 12 at bottom portion BT of trench TR (see FIG. 15). Gate insulating film 15 has a thickness of about 90 nm, for example.

Next, a NO annealing step is performed. Specifically, in an atmosphere including nitrogen, silicon carbide substrate 10 having gate insulating film 15 formed on first main surface 10a is heated at a temperature of not less than 1250° C. and 1350° C., for example. Examples of the gas including nitrogen include dinitrogen oxide diluted with nitrogen by 10%, and the like. Preferably, silicon carbide substrate 10 having gate insulating film 15 formed thereon is held for about 60 minutes in the gas including nitrogen.

Next, gate electrode 27 is formed to fill the groove formed by gate insulating film 15. Gate electrode 27 is composed of a material including polysilicon including an impurity, for example. Next, interlayer insulating film 21 is formed to cover gate electrode 27 and in contact with contact region 18 and source region 14. Interlayer insulating film 21 includes a TEOS oxide film and a PSG, for example.

Next, interlayer insulating film 21 is removed from a region to be provided with source electrode 16, with the result that each of source region 14 and contact region 18 is exposed through interlayer insulating film 21. Next, source electrode 16 is formed in contact with source region 14 and contact region 18 at first main surface 10a of silicon carbide substrate 10 by sputtering, for example. Source electrode 16 includes Ni and Ti, for example. Preferably, source electrode 16 is composed of a material including TiAlSi. Next, silicon carbide substrate 10 having source electrode 16 formed thereon in contact with each of source region 14 and contact region 18 at first main surface 10a of silicon carbide substrate 10 is subjected to RTA (Rapid Thermal Anneal) for about 2 minutes at a temperature of not less than 900° C. and not more than 1100° C., for example. In this way, at least a portion of source electrode 16 reacts with silicon included in the silicon carbide substrate and is accordingly silicided. In this way, source electrode 16 in ohmic junction with source region 14 is formed. Preferably, source electrode 16 is in ohmic junction with each of source region 14 and contact region 18.

With reference to FIG. 1, source interconnection 19 is formed in contact with source electrode 16 to cover interlayer insulating film 21. Source interconnection 19 is preferably composed of a material including Al, such as a material including AlSiCu. Next, protective film 24 is formed to cover source interconnection 19. Protective film 24 is composed of a material including a nitride film and polyimide, for example. Next, drain electrode 20 composed of NiSi is formed in contact with second main surface 10b of silicon carbide substrate 10, for example. Drain electrode 20 may be TiAlSi or the like, for example. Drain electrode 20 is preferably formed by sputtering, but may be formed by evaporation. After the formation of drain electrode 20, drain electrode 20 is heated by laser annealing, for example. Accordingly, at least a portion of drain electrode 20 is silicided, thereby forming drain electrode 20 in ohmic junction with silicon carbide single crystal substrate 11. In the manner described above, MOSFET 1 shown in FIG. 1 is manufactured.

Next, the following describes function and effect of MOSFET 1 serving as the silicon carbide semiconductor device according to the first embodiment and the method for manufacturing MOSFET 1.

In accordance with the method for manufacturing MOSFET 1 according to the first embodiment, base region 13 having an impurity concentration lower than that of embedded region 17 is formed in contact with first impurity region 12 and embedded region 17 by epitaxial growth after forming embedded region 17 by performing ion implantation into first impurity region 12. Accordingly, ion implantation energy can be reduced as compared with a case where embedded region 17 is formed by performing ion implantation via the surface of base region 13 after forming base region 13. As a result, flow of current can be suppressed from being hindered due to high ion implantation energy causing channeling and multiple scattering of ions and resulting in expansion of the impurity introduced by the ion implantation. Moreover, since the pn junction formed by first impurity region 12 and embedded region 17 is formed at a location deep and distant from first main surface 10a of silicon carbide substrate 10, electric field in trench TR can be shielded effectively. Further, since second impurity region 13 serving as the channel is formed by epitaxial growth, a high-quality channel can be realized.

Moreover, in accordance with the method for manufacturing MOSFET 1 according to the first embodiment, in the step of forming trench TR, trench TR is formed such that side portion SW of trench TR is separated from embedded region 17 by first impurity region 12. A distance is not less than 0.2 μm and not more than 5 μm between side portion SW of trench TR and the side surface of embedded region 17 facing side portion SW in the direction parallel to first main surface 10a. When distance D between side portion SW of trench TR and the side surface of embedded region 17 is smaller than 0.2 μm, current can be prevented from being expanded from the channel, thereby increasing on resistance. When distance D between side portion SW of trench TR and the side surface of embedded region 17 is larger than 5 μm, an effect of shielding the electric field in bottom portion BT of trench TR by embedded region 17 is decreased.

Further, in accordance with the method for manufacturing MOSFET 1 according to the first embodiment, depth H1 of trench TR in the normal direction of first main surface 10a is not less than 0.3 μm and not more than 3 μm, and is smaller than the width of trench TR in the direction parallel to first main surface 10a. When depth H1 of trench TR is less than 0.3 μm, it becomes difficult to form a channel. When depth H1 of trench TR is more than 3 μm, it becomes difficult to control the shape of the trench.

Further, in accordance with the method for manufacturing MOSFET 1 according to the first embodiment, first main surface 10a of silicon carbide substrate 10 is a plane angled off relative to the {0001} plane in the off direction. Side portion SW of trench TR includes plane SW1 having the plane orientation perpendicular to the off direction and perpendicular to the normal direction of first main surface 10a. Since the side wall of the trench is mainly constituted of the plane normal to the off direction, deviation of the plane orientation of the side wall can become minimum. Moreover, when the off direction is, for example, the <11-20> direction, flatter silicon carbide epitaxial layer 5 can be formed.

Further, in accordance with the method for manufacturing MOSFET 1 according to the first embodiment, in the step of forming embedded region 17, ion implantation is performed in the direction perpendicular to the off direction and inclined from the normal direction of first main surface 10a by not less than 2° and not more than 10° relative to the direction parallel to first main surface 10a. By performing ion implantation in the direction perpendicular to the off direction and inclined by not less than 2° and not more than 10° relative to the direction parallel to first main surface 10a, channeling can be suppressed effectively. Moreover, when forming embedded region 17 at corner portion CR of bottom portion BT of trench TR at which the breakdown voltage is likely to be deteriorated, occurrence of location deviation of embedded region 17 can be suppressed effectively.

Further, in accordance with the method for manufacturing MOSFET 1 according to the first embodiment, in the step of forming trench TR, when viewed in the normal direction of first main surface 10a, trench TR is formed such that corner portion CR of bottom portion BT of trench TR overlaps with embedded region 17. Accordingly, it is possible to shield an electric field at corner portion CR of bottom portion BT of trench TR at which the breakdown voltage is likely to be deteriorated.

In accordance with MOSFET 1 according to the first embodiment, embedded region 17 has locations each having an impurity concentration four times as large as an impurity concentration of base region 13, and a distance is not more than 0.3 μm from (i) a location closest to base region 13 among the locations to (ii) a boundary portion between base region 13 and embedded region 17 in the normal direction of first main surface 10a. This provides an effect of sufficiently shielded electric field by embedded region 17 to reduce a capacitance of the source portion.

Moreover, in accordance with MOSFET 1 according to the first embodiment, when viewed in the normal direction of first main surface 10a, corner portion CR of bottom portion BT of trench TR is disposed to overlap with embedded region 17. Accordingly, it is possible to shield an electric field at corner portion CR of bottom portion BT of trench TR at which the breakdown voltage is likely to be deteriorated.

### Second Embodiment

Next, the following describes a configuration of a MOSFET serving as a silicon carbide semiconductor device according to a second embodiment of the present invention. The MOSFET according to the second embodiment is different from the MOSFET according to the first embodiment in that embedded region 17 is in contact with bottom portion BT of trench TR. The other configuration of the MOSFET according to the second embodiment is the same as that of the MOSFET according to the first embodiment. Therefore, the same or corresponding portions are given the same reference characters and are not described repeatedly.

With reference to FIG. 16, embedded region 17 is provided to extend from bottom portion BT of trench TR toward second main surface 10b. Each of the side portion and lower end of embedded region 17 is in contact with first impurity region 12. Embedded region 17 has p type conductivity and has an impurity concentration higher than that of base region 13. Embedded region 17 is short-circuited (connected) with contact region 18 at part of regions in silicon carbide substrate 10. Gate insulating film 15 is in contact with both embedded region 17 and first impurity region 12 at bottom portion BT of trench TR. Contact region 18 does not extend through base region 13, and has a lower end portion located at the first main surface 10a side relative to the lower end portion of base region 13.

Preferably, width W1 of embedded region 17 is smaller than width W2 of bottom portion BT of trench TR in the direction parallel to first main surface 10a. A value obtained by subtracting width W1 of embedded region 17 from width W2 of bottom portion BT of trench TR is not less than 0.1 μm and not more than 0.4 μm, for example. When viewed in the normal direction of first main surface 10a, embedded region 17 is preferably formed not to be wider than bottom portion BT of the trench. When width W2 of bottom portion BT of trench TR is set to be larger than width W1 of embedded region 17 by not less than 0.1 μm, current flowing from the channel can be expanded without being hindered by a depletion layer from the side surface of embedded region 17, thus reducing the on resistance. When width W2 of bottom portion BT of trench TR is set to be smaller than width W1 of embedded region 17 by not more than 0.4 μm, electric field can be suppressed from being concentrated at the corner portion at which side portion SW and bottom portion BT of trench TR are connected to each other.

With reference to FIG. 16, when viewed in a cross sectional view (field of view in the direction parallel to first main surface 10a of silicon carbide substrate 10, i.e., field of view of FIG. 16), trench TR preferably has the same symmetry axis as that of embedded region 17 and is preferably in line symmetry (bilateral symmetry) with respect to the symmetry axis. Because the shape of trench TR is bilaterally symmetrical, electric field can be suppressed from being concentrated locally.

Next, the following describes a method for manufacturing MOSFET 1 serving as the silicon carbide semiconductor device according to the second embodiment. The method for manufacturing the MOSFET according to the second embodiment is different from the method for manufacturing the MOSFET according to the first embodiment in that in the step of forming the trench, the trench is formed such that the embedded region is exposed at the bottom portion of the trench. The other configuration of the method for manufacturing the MOSFET according to the second embodiment is the same as those of the method for manufacturing the MOSFET according to the first embodiment. Therefore, the same or corresponding portions are given the same reference characters and are not described repeatedly.

With reference to FIG. 7 and FIG. 8, an n type epitaxial layer forming step (S10: FIG. 6) is performed in the same manner as described in the first embodiment. Next, a p type embedded region forming step (S20: FIG. 6) is performed. Specifically, with reference to FIG. 17, an ion implantation mask 31 is formed on first impurity region 12 of silicon carbide epitaxial layer 5. The ion implantation mask is composed of a material including a TEOS oxide film, and ion implantation mask 31 has a thickness of 1.6 μm, for example. Next, CHF₃ and O₂ are employed to perform RF etching onto ion implantation mask 31. Accordingly, a through film of about 80 nm is left at a portion to be subjected to ion implantation, for example. Next, using ion implantation mask 31 having the through film, ion implantation is performed into first impurity region 12 of silicon carbide epitaxial layer 5. For example, Al (aluminum) ions are implanted into silicon carbide epitaxial layer 5 through the through film in a direction of arrows, thereby forming embedded region 17 having p type conductivity and an impurity concentration higher than that of base region 13 (see FIG. 17). When viewed in a cross section, embedded region 17 has a plurality of portions disposed with an interval therebetween. That is, when viewed in a cross section, embedded region 17 is disposed cyclically in the direction parallel to first main surface 10a of silicon carbide substrate 10 and along direction a21 (see FIG. 3).

Ion implantation conditions, such as acceleration voltage and dose amount, are adjusted such that the impurity concentration of embedded region 17 at the second main surface 10b side becomes higher than the impurity concentration of embedded region 17 at the first main surface 10a side. Preferably in the step of forming embedded region 17, for example, aluminum ions are implanted in the direction perpendicular to off direction a1 and inclined from the normal direction of first main surface 10a by not less than 2° and not more than 10° relative to the direction parallel to first main surface 10a. The direction perpendicular to off direction al and parallel to first main surface 10a is the <1-100> direction, for example. By performing the ion implantation into first impurity region 12 as described above, embedded region 17 is formed to have p type conductivity different from n type conductivity and to be disposed periodically.

Next, in the same manner as described in the first embodiment, a p type epitaxial layer forming step (S40: FIG. 6) and an n type source region forming step (S50: FIG. 6) are performed.

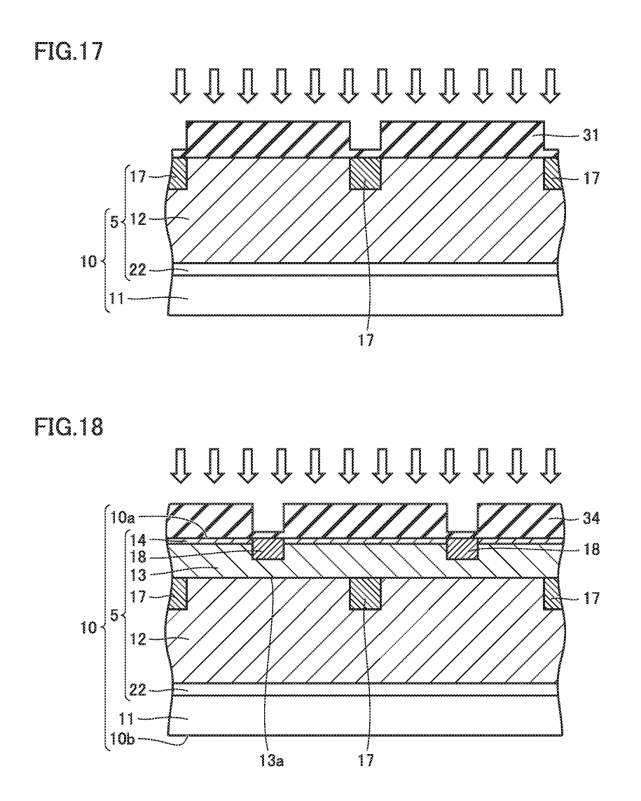

Next, a p type contact region forming step (S60: FIG. 6) is performed. With reference to FIG. 18, an ion implantation mask 34 is formed on base region 13 and source region 14. The ion implantation mask is composed of a material including a TEOS oxide film, and ion implantation mask 31 has a thickness of 1.6 μm, for example. Next, CHF₃ and O₂ are employed to perform RF etching onto ion implantation mask 34. Accordingly, a through film of about 80 nm is left above a region to be provided with contact region 18, for example. Next, ion implantation mask 34 having the through film is employed to perform ion implantation into base region 13 of silicon carbide epitaxial layer 5. For example, aluminum ions are implanted into each of base region 13 and source region 14 up to a depth at the second main surface 10b side relative to the lower end of source region 14 and at the first main surface 10a side relative to lower end 13a of base region 13. Accordingly, contact region 18 having p type conductivity is formed between the portions of source region 14 and base region 13 (see FIG. 18).

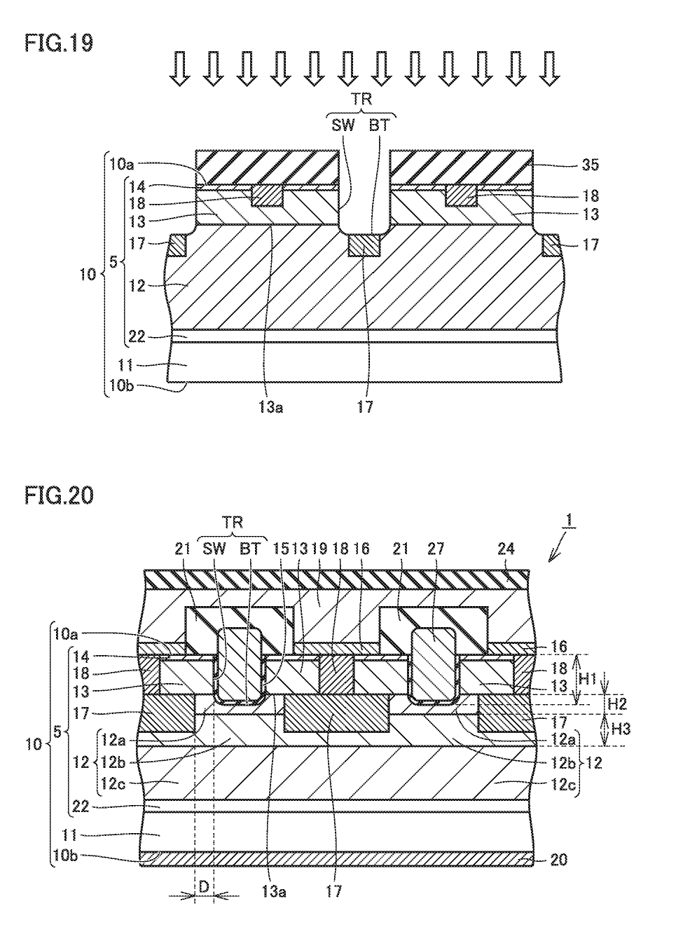

Next, a trench forming step (S70: FIG. 6) is performed. With reference to FIG. 19, an etching mask 35 is formed on source region 14 and contact region 18. Etching mask 35 is composed of a material including a TEOS oxide film, and etching mask 35 has a thickness of 1.6 μm, for example. Next, CHF₃ and O₂ are employed to perform RF etching onto etching mask 35 on regions to be provided with trenches TR, thereby forming openings in etching mask 35. Next, etching is performed to silicon carbide substrate 10 using etching mask 35 thus provided with the openings above the regions to be provided with trenches TR. For example, SF₆ and O₂ are employed to perform ECR plasma etching onto silicon carbide substrate 10. Accordingly, trenches TR are formed to each have (i) side portion SW continuous to first main surface 10a of silicon carbide substrate 10 and (ii) bottom portion BT continuous to side portion SW. Source region 14, base region 13, and first impurity region 12 are exposed at side portion SW of trench TR, and first impurity region 12 and embedded region 17 are exposed at bottom portion BT of trench TR. In other words, trench TR is formed to expose embedded region 17 at bottom portion BT of trench TR.

With reference to FIG. 3 and FIG. 19, the cycle of trenches TR in direction a21 is the same as the cycle of embedded region 17 in direction a2. Specifically, one embedded region 17 is provided in contact with a corresponding one of bottom portions BT of the plurality of trenches TR. In this way, trenches TR are formed to each have (i) side portion SW extending to first impurity region 12 through base region 13 and source region 14 and (ii) bottom portion BT continuous to side portion SW, and to be disposed at the same cycle as embedded region 17. Preferably, depth H of trench TR in the normal direction of first main surface 10a of silicon carbide substrate 10 is not less than 0.3 μm and not more than 3 μm, and is smaller than the width of trench TR in the direction parallel to first main surface 10a of silicon carbide substrate 10.

Preferably, trench TR is formed such that the width of bottom portion BT of trench TR becomes larger than the width of embedded region 17 in the direction parallel to first main surface 10a of silicon carbide substrate 10. With reference to FIG. 16, a value obtained by subtracting width W1 of embedded region 17 from width W2 of bottom portion BT of trench TR is not less than 0.1 μm and not more than 0.4 μm, for example. Preferably, when viewed in the normal direction of first main surface 10a, trench TR is formed such that embedded region 17 is not wider than bottom portion BT of the trench.

Next, in the same manner as described in the first embodiment, a gate oxide film forming step (S80: FIG. 6), a gate electrode forming step (S90: FIG. 6), and the like are performed, thereby manufacturing the MOSFET shown in FIG. 16.

Next, the following describes function and effect of MOSFET 1 serving as the silicon carbide semiconductor device according to the second embodiment.

In accordance with the method for manufacturing MOSFET 1 according to the second embodiment, in the step of forming trench TR, trench TR is formed to expose embedded region 17 at bottom portion BT of trench TR. Accordingly, bottom portion BT of trench TR can be effectively shielded from high electric field, thereby improving the breakdown voltage.

Moreover, in accordance with the method for manufacturing MOSFET 1 according to the second embodiment, the width of bottom portion BT of trench TR is larger than the width of embedded region 17 in the direction parallel to first main surface 10a. Accordingly, flow of current can be suppressed from being hindered by a depletion layer expanding from the side surface of embedded region 17. As a result, the on resistance can be reduced.

### Third Embodiment

Next, the following describes a configuration of a MOSFET serving as a silicon carbide semiconductor device according to a third embodiment of the present invention. The MOSFET according to the third embodiment is different from the MOSFET according to the first embodiment in that first impurity region 12 has a first region 12a, a second region 12b, and a third region 12c. The other configuration of the MOSFET according to the third embodiment is the same as that of the MOSFET according to the first embodiment. Therefore, the same or corresponding portions are given the same reference characters and are not described repeatedly.

With reference to FIG. 20, first impurity region 12 has: a third region 12c provided on buffer layer 22; a second region 12b provided on third region 12c; and a first region 12a provided on second region 12b. First region 12a is in contact with base regions 13. Second region 12b is in contact with first region 12a, and is located opposite to base region 13 when viewed from first region 12a. Third region 12c is in contact with second region 12b, and is located opposite to first region 12a when viewed from second region 12b.

Each of first region 12a, second region 12b, and third region 12c includes an n type impurity such as nitrogen and has therefore n type conductivity. Second region 12b has an impurity concentration higher than that of first region 12a. Third region 12c has an impurity concentration lower than that of second region 12b. Preferably, the concentration of the impurity in first region 12a such as nitrogen is not more than 1.5×10¹⁶ cm⁻³. The concentration of the impurity in first region 12a such as nitrogen may be higher than the concentration of the impurity in third region 12c such as nitrogen. Preferably, the concentration of the impurity in second region 12b such as nitrogen is not less than 2×10¹⁶ cm⁻³. The concentration of the impurity in second region 12b such as nitrogen may be not more than 2×10¹⁷ cm⁻³. When the concentration of the impurity in second region 12b such as nitrogen is not more than 2×10¹⁷ cm⁻³, embedded region 17 can be suppressed from being broken due to electric field concentrated on embedded region 17.

Preferably, a thickness H2 of first region 12a in the normal direction of first main surface 10a is not less than 0.1 μm and not more than 0.5 μm, more preferably, not less than 0.1 μm and not more than 0.4 μm. When thickness H2 of first region 12a is not less than 0.1 μm, electric field in trench TR can be suppressed effectively from being concentrated, thereby improving the breakdown voltage. When thickness H2 of first region 12a is not more than 0.5 μm, the on resistance can be suppressed from being increased. Preferably, the thickness of second region 12b in the normal direction of first main surface 10a is not less than 0.3 μm and not more than 2 μm. When thickness H3 of second region 12b is not less than 0.3 μm, carriers are effectively gathered in trench TR, thus reducing the on resistance. When thickness H3 of second region 12b is not more than 2 μm, the on resistance can be suppressed from being increased.

Preferably, the end portion of embedded region 17 at the second main surface 10b side is in contact with second region 12b. The side portions of embedded region 17 are in contact with each of first region 12a and second region 12b. The thickness of embedded region 17 is larger than the thickness of first region 12a in the normal direction of first main surface 10a. When viewed in a cross section, first region 12a and a portion of second region 12b are formed between two portions of embedded region 17. The end portion of embedded region 17 at the second main surface 10b side may be located at the second main surface 10b side relative to a boundary portion between second region 12b and third region 12c. That is, the end portion of embedded region 17 at the second main surface 10b side may be in contact with third region 12c.

In first main surface 10a of silicon carbide substrate 10, trench TR is formed to have (i) side portion SW continuous to first main surface 10a and (ii) bottom portion BT continuous to side portion SW. Side portion SW of trench TR extends to first region 12a through each of source region 14 and base region 13, and bottom portion BT of trench TR is located in first region 12a. That is, first region 12a, base region 13, and source region 14 are in contact with side portion SW of the trench, and first region 12a is in contact with bottom portion BT of trench TR.

Gate insulating film 15 is composed of silicon dioxide and is provided in contact with side portion SW and bottom portion BT of trench TR, for example. Gate insulating film 15 is in contact with first region 12a, base region 13, and source region 14 at side portion SW of trench TR, and is in contact with first region 12a at bottom portion BT of trench TR. Preferably, bottom portion BT of trench TR is provided to be separated from each of second region 12b and third region 12c.

Next, the following describes a method for manufacturing MOSFET 1 serving as the silicon carbide semiconductor device according to the third embodiment. The method for manufacturing the MOSFET according to the third embodiment is different from the method for manufacturing the MOSFET according to the first embodiment in that the method includes a step of forming the first region and a step of forming the second region. The other configuration of the method for manufacturing the MOSFET according to the third embodiment is the same as that of the method for manufacturing the MOSFET according to the first embodiment. Therefore, the same or corresponding portions are given the same reference characters and are not described repeatedly.

With reference to FIG. 7 to FIG. 10, an n type epitaxial layer forming step (S10: FIG. 6), a p type embedded region forming step (S20: FIG. 6), and the like are performed in the same manner as described in the first embodiment.

Next, an n type second region forming step is performed. Specifically, a portion of ion implantation mask 31 above a region to be provided with second region 12b is removed, with the result that a through film 32 having a thickness of 80 nm is left, for example. Next, nitrogen ions are implanted from above through film 32 into both embedded region 17 and third region 12c in the direction of arrows, for example. Accordingly, when viewed in a cross sectional view, second region 12b is formed at a region interposed between two portions of embedded region 17.

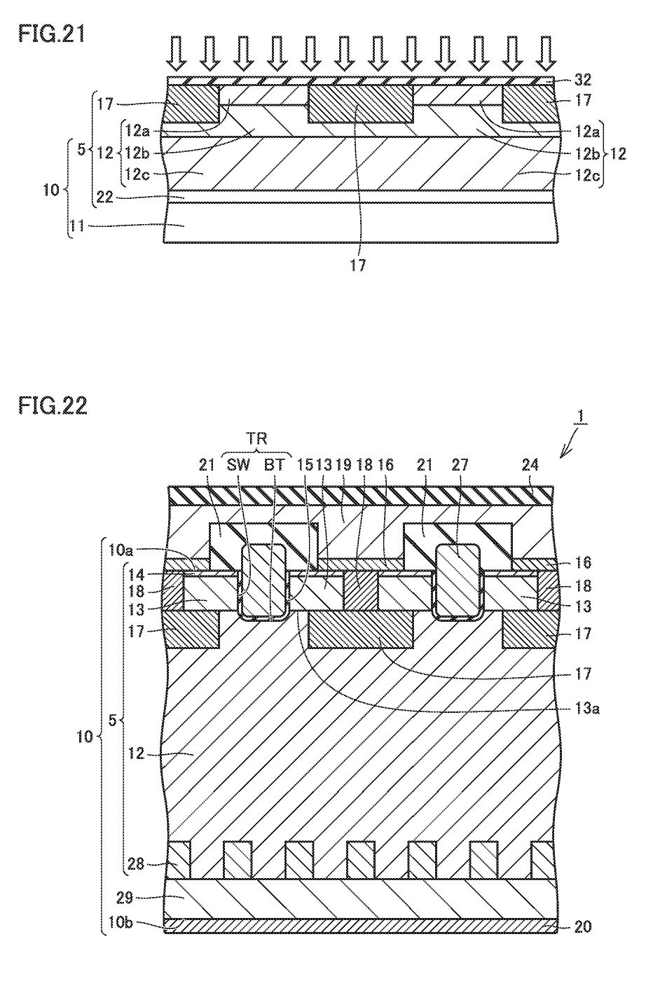

Next, an n type first region forming step is performed. Specifically, nitrogen ions are implanted from above through film 32 into both embedded region 17 and second region 12b in the direction of arrows, for example. Accordingly, first region 12a is formed at a region interposed between through film 32 and second region 12b (see FIG. 21). Preferably, ion implantation energy (acceleration voltage) in the step of forming second region 12b is larger than ion implantation energy (acceleration voltage) in the step of forming first region 12a. In other words, after implanting nitrogen ions into third region 12c using a first acceleration voltage, nitrogen ions are implanted into second region 12b using a second acceleration voltage smaller than the first acceleration voltage, for example. Next, through film 32 is removed from the respective surfaces of embedded region 17 and first region 12a.

Preferably in the step of forming first region 12a and second region 12b, for example, nitrogen ions are implanted in the direction perpendicular to off direction a1 and inclined from the normal direction of first main surface 10a by not less than 2° and not more than 10° relative to the direction parallel to first main surface 10a. The direction perpendicular to off direction al and parallel to first main surface 10a is the <1-100> direction, for example.

In this way, in the region interposed by embedded region 17, first region 12a and second region 12b having a higher impurity concentration than that of first region 12a are formed. Preferably, the impurity concentration of first region 12a is not more than 1.5×10¹⁶ cm⁻³. Preferably, the impurity concentration of second region 12b is not less than 2×10¹⁶ cm⁻³. Preferably, the thickness of first region 12a in the normal direction of first main surface 10a is not less than 0.1 μm and not more than 0.5 μm. Preferably, the thickness of second region 12b in the normal direction of first main surface 10a is not less than 0.3 μm and not more than 2 μm. It should be noted that in the above description, it has been illustrated that the n type second region forming step and the n type first region forming step are performed after performing the p type embedded region forming step; however, the p type embedded region forming step may be performed after performing the n type second region forming step and the n type first region forming step.

Next, in the same manner as described in the first embodiment, a p type epitaxial layer forming step (S40: FIG. 6), an n type source region forming step (S50: FIG. 6), a p type contact region forming step (S60: FIG. 6), a trench forming step (S70: FIG. 6), a gate oxide film forming step (S80: FIG. 6), a gate electrode forming step (S90: FIG. 6), and the like are performed, thereby manufacturing MOSFET 1 shown in FIG. 20.

Next, the following describes function and effect of MOSFET 1 serving as the silicon carbide semiconductor device according to the third embodiment.

In accordance with MOSFET 1 according to the third embodiment, first impurity region 12 has first region 12a, second region 12b, and third region 12c, first region 12a being in contact with second impurity region 13, second region 12b being in contact with first region 12a, second region 12b being located opposite to second impurity region 13 when viewed from first region 12a, second region 12b having an impurity concentration higher than an impurity concentration of first region 12a, third region 12c being in contact with second region 12b, third region 12c being located opposite to first region 12a when viewed from second region 12b, third region 12c having an impurity concentration lower than the impurity concentration of second region 12b. In this way, during off time, a depletion layer is expanded in first region 12a having the low impurity concentration to relax electric field in trench TR, whereby a high breakdown voltage can be maintained. During on time, with voltage applied to gate electrode 27, carriers can be gathered around trench TR from second region 12b having the high impurity concentration. As a result, high conductivity can be realized, thus reducing the on resistance. That is, the on resistance can be reduced and the breakdown voltage can be improved.

### Fourth Embodiment

Next, the following describes a configuration of an IGBT (Insulated Gate Bipolar Transistor) serving as a silicon carbide semiconductor device according to a fourth embodiment of the present invention. The IGBT according to the fourth embodiment is different from the MOSFET according to the first embodiment in that: first impurity region 12 has a thick thickness of about 100 μm; first impurity region 12 has an impurity concentration of about not less than 5×10¹⁴ cm⁻³ and not more than 1×10¹⁵ cm⁻³; and the IGBT has a p type epitaxial layer in contact with a backside electrode; and the IGBT has a carrier injection region in contact with the p type epitaxial layer. The other configuration of the IGBT according to the fourth embodiment is the same as those of the MOSFET according to the first embodiment. Therefore, the same or corresponding portions are given the same reference characters and are not described repeatedly.

With reference to FIG. 22, IGBT 1 according to the fourth embodiment mainly includes a silicon carbide substrate 10, a gate electrode 27, a gate insulating film 15, an interlayer insulating film 21, an emitter electrode 16, an emitter interconnection 19, a collector electrode 20, and a protective film 24. Silicon carbide substrate 10 mainly has a first impurity region 12, a base region 13, an emitter region 14, a contact region 18, a p type epitaxial layer 29, and a carrier injection region 28. First impurity region 12 has a thickness of about 100 μm, for example. First impurity region 12 includes an n type impurity such as nitrogen and has n type conductivity, for example. The concentration of the impurity in first impurity region 12 such as nitrogen is about not less than 5×10 ¹⁴ cm⁻³ and not more than 1×10¹⁵ cm⁻³, for example.

P type epitaxial layer 29 (second conductivity type epitaxial layer 29) includes a p type impurity such as aluminum, and therefore has p type conductivity, for example. P type epitaxial layer 29 is provided in contact with first impurity region 12 to constitute second main surface 10b of silicon carbide substrate 10. P type epitaxial layer 29 is in contact with collector electrode 20 at second main surface 10b of silicon carbide substrate 10. Collector electrode 20 includes Ti and Al, for example. Carrier injection region 28 includes a p type impurity such as aluminum and therefore has p type conductivity, for example. Carrier injection region 28 is in contact with p type epitaxial layer 29 and first impurity region 12, and has an impurity concentration higher than that of p type epitaxial layer 29. When viewed in a cross section, carrier injection region 28 has portions cyclically provided. When viewed in a cross section, carrier injection region 28 is provided cyclically with an interval therebetween in the short side direction (see FIG. 3) of trench TR. Preferably, the concentration of the p type impurity in carrier injection region 28 such as aluminum is the same as the concentration of the p type impurity in embedded region 17 or is higher than the concentration of the impurity in embedded region 17.

Next, the following describes a method for manufacturing IGBT 1 serving as the silicon carbide semiconductor device according to the fourth embodiment. The method for manufacturing the IGBT according to the fourth embodiment is different from the method for manufacturing the MOSFET according to the first embodiment in that carrier injection region 28 and p type epitaxial layer 29 are formed. The other configuration of the method for manufacturing the IGBT according to the fourth embodiment is substantially the same as those of the method for manufacturing the MOSFET according to the first embodiment. Therefore, the same or corresponding portions are given the same reference characters and are not described repeatedly.

By removing silicon carbide single crystal substrate 11 from silicon carbide substrate 10, first impurity region 12 is exposed at the backside surface side. Next, into the exposed first impurity region 12, ions of a p type impurity such as aluminum are implanted from the backside surface side with a certain interval. Preferably, the ions of the p type impurity are implanted into first impurity region 12 such that the concentration of the p type impurity in carrier injection region 28 is the same as the concentration of the p type impurity in embedded region 17 or is higher than the concentration of the p type impurity in embedded region 17. By performing ion implantation into first impurity region 12 from the second main surface 10b side of silicon carbide substrate 10 as described above, carrier injection region 28 having p type conductivity is formed to be disposed cyclically.

Next, p type epitaxial layer 29 is formed by epitaxial growth in contact with both carrier injection region 28 and first impurity region 12. P type epitaxial layer 29 includes a p type impurity such as aluminum, for example. After forming p type epitaxial layer 29, ions of a p type impurity such as aluminum may be further implanted into p type epitaxial layer 29. Next, for example, p type epitaxial layer 29 is joined to a polycrystal silicon carbide substrate (not shown), a surface step is performed, and then the polycrystal silicon carbide substrate is removed from p type epitaxial layer 29.

Next, collector electrode 20 is formed opposite to carrier injection region 28 when viewed from p type epitaxial layer 29. Collector electrode 20 includes Ti and Al, for example. Next, laser annealing is performed onto collector electrode 20, thereby bringing collector electrode 20 and p type epitaxial layer 29 into ohmic junction with each other. In the manner described above, IGBT 1 shown in FIG. 22 is manufactured.

Next, the following describes function and effect of IGBT 1 serving as the silicon carbide semiconductor device according to the fourth embodiment.

In accordance with the method for manufacturing silicon carbide semiconductor device 1 according to the fourth embodiment, the step of forming silicon carbide substrate 10 further includes a step of forming carrier injection region 28 having second conductivity type and disposed cyclically, by performing ion implantation into first impurity region 12 from the second main surface 10b side. Accordingly, injection of carriers from carrier injection region 28 can be facilitated, thereby reducing on resistance.

In accordance with silicon carbide semiconductor device 1 according to the fourth embodiment, silicon carbide substrate 10 further includes p type epitaxial layer 29 and carrier injection region 28, p type epitaxial layer 29 having p type conductivity, p type epitaxial layer 29 constituting second main surface 10b, p type epitaxial layer 29 being provided in contact with first impurity region 12, carrier injection region 28 having p type conductivity, carrier injection region 28 being in contact with p type epitaxial layer 29 and first impurity region 12, carrier injection region 28 having an impurity concentration higher than the impurity concentration of p type epitaxial layer 29, carrier injection region 28 being disposed cyclically. Accordingly, injection of carriers from carrier injection region 28 can be facilitated, thereby reducing on resistance.

It should be noted that in each of the embodiments, it has been illustrated that the first conductivity type is n type and the second conductivity type is p type; however, the first conductivity type may be p type and the second conductivity type may be n type. Further, it has been illustrated that side portion SW of trench TR is substantially perpendicular to first main surface 10a of silicon carbide substrate 10; however, side portion SW of trench TR may be inclined relative to first main surface 10a.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: silicon carbide semiconductor device (MOSFET, IGBT); 5: silicon carbide epitaxial layer; 10: silicon carbide substrate; 10a: first main surface; 10b: second main surface; 11: silicon carbide single crystal substrate; 12: first impurity region; 12a: first region; 12b: second region; 12c: third region; 13: second impurity region (base region); 13a: end portion; 14: third impurity region (source region, emitter region); 15: gate insulating film; 16: source electrode (emitter electrode); 17: embedded region; 17a: first embedded region; 17b: second embedded region; 18: contact region; 19: source interconnection (emitter interconnection); 20: drain electrode (collector electrode); 21: interlayer insulating film; 22: buffer layer; 24: protective film; 27: gate electrode; 28: carrier injection region; 29: second conductivity type epitaxial layer (p type epitaxial layer); 31, 33, 34: ion implantation mask; 32: through film; 35: etching mask; 40: semiconductor chip; 41: guard ring; BT: bottom portion; CH: channel region; CR: corner portion; SW: side portion; SW1: first side portion (plane); SW2: second side portion; TR: trench; a1: off direction; a11: in-plane off direction; a21: direction; d1, d2: impurity concentration.

1. A method for manufacturing a silicon carbide semiconductor device, the method comprising steps of:
forming a silicon carbide substrate having a first main surface and a second main surface opposite to the first main surface,
the step of forming the silicon carbide substrate includes steps of
forming a first impurity region having a first conductivity type by epitaxial growth,
forming an embedded region by performing ion implantation into the first impurity region, the embedded region having a second conductivity type different from the first conductivity type, the embedded region being disposed cyclically,
forming a second impurity region by epitaxial growth, the second impurity region being in contact with the first impurity region and the embedded region, the second impurity region having the second conductivity type, the second impurity region having an impurity concentration lower than an impurity concentration of the embedded region, and
forming a third impurity region having the first conductivity type, the third impurity region being separated from the first impurity region by the second impurity region;
forming a trench having a side portion and a bottom portion, the side portion extending to the first impurity region through the second impurity region and the third impurity region, the bottom portion being continuous to the side portion, the trench being disposed at the same cycle as the embedded region; and
forming a gate insulating film in contact with the first impurity region, the second impurity region, and the third impurity region at the side portion of the trench;
wherein the first impurity region includes a first region, a second region and a third region,
the first region is in contact with the second impurity region,
the second region is in contact with the first region,
the third region is in contact with the second region,
the second region is between the first region and the third region,
an impurity concentration of the second region is higher than an impurity concentration of the first region, and
an impurity concentration of the third region is lower than an impurity concentration of the second region.

2. The method for manufacturing the silicon carbide semiconductor device according to claim 1, wherein
in the step of forming the trench, the trench is formed such that the side portion of the trench is separated from the embedded region by the first impurity region, and
a distance is not less than 0.2 μm and not more than 5 μm between the side portion of the trench and the side surface of the embedded region facing the side portion in a direction parallel to the first main surface.

3. (canceled)

4. (canceled)

5. The method for manufacturing the silicon carbide semiconductor device according to claim 1, wherein a depth of the trench in a normal direction of the first main surface is not less than 0.3 μm and not more than 3 μm and is smaller than a width of the trench in a direction parallel to the first main surface and perpendicular to an in-plane off direction.

6. The method for manufacturing the silicon carbide semiconductor device according to claim 1, wherein
the silicon carbide substrate has a hexagonal crystal structure,
the first main surface of the silicon carbide substrate corresponds to a plane angled off relative to a {0001} plane in an off direction, and
the side portion of the trench includes a plane having a plane orientation perpendicular to the off direction and perpendicular to a normal direction of the first main surface.

7. The method for manufacturing the silicon carbide semiconductor device according to claim 1, wherein in the step of forming the embedded region, the ion implantation is performed in a direction perpendicular to an off direction and inclined from the normal direction of the first main surface by not less than 2° and not more than 10° relative to a direction parallel to the first main surface.

8. The method for manufacturing the silicon carbide semiconductor device according to claim 1, wherein in the step of forming the trench, when viewed from the normal direction of the first main surface, the trench is formed such that a corner portions of the bottom portion of the trench overlaps with the embedded region.

9. (canceled)

10. (canceled)

11. (canceled)

12. (canceled)

13. (canceled)
